(19) United States
(12) Patent Application Publication
(10) Pub. No.: US 2007/0209437 A1
(43) Pub. Date: Sep. 13, 2007

(54) Magnetic MEMS device

(75) Inventors: Song Sheng Xue, Edina, MN (US); Nurul Amin, Woodbury, MN (US); Patrick Joseph Ryan, Saint Paul, MN (US); John Stuart Wright, Minneapolis, MN (US); Jeffery Kenneth Berkowitz, Carver, MN (US); Insik Jin, Eagan, MN (US)

Correspondence Address: Seagate Technology LLC, 7801 Computer Ave. S., NRW097, Bloomington, MN, 55435, US

(73) Assignee: Seagate Technology LLC

(21) Appl. No.: 11/348,930

(22) Filed: Apr. 7, 2006

Related U.S. Application Data
(60) Provisional application No. 60/727,966, filed on Oct. 18, 2005.

(51) Int. Cl. B81B 7/02; G01P 15/105; G01B 7/00; H01L 27/22; H01L 43/00

(52) U.S. Cl. 73/514.31; 324/207.15; 257/421

(57) ABSTRACT

The present invention relates to magnetic micro-electromechanical systems (MEMS) or magnetic MEMS devices, particularly electronic devices in which a member adjoins a base or substrate and extends from the substrate proximate to a magnetic field element having an altered output associated with movement of the member. The first magnetic field element is adapted to emit or detect a magnetic field and positioned proximate to the member, and the second magnetic field element adapted to emit or detect a magnetic field and positioned proximate to the base or substrate, such that movement of the member in a first direction by a non-magnetic force results in a variation of magnetic field strength associated with displacement of the sensor in a first direction. The invention also relates to methods for fabricating magnetic MEMS devices, transducers, sensors, and accelerometers.

### CROSS REFERENCE TO RELATED APPLICTIONS

The present invention claims priority to U.S. Provisional Application No. 60/727,966, filed Oct. 18, 2005, and entitled “Magnetic MEMS Sensor.”

### FIELD OF THE INVENTION

This invention relates to micro-electro-mechanical systems (MEMS) and electronic devices, particularly magnetic MEMS devices useful as sensors such as accelerometers. The invention also relates to methods for fabricating magnetic MEMS devices.

### BACKGROUND

Micro-electro-mechanical systems (MEMS) are a class of micron-scale devices, made using semi-conductor processing, that integrate electronic and mechanical device functions on a single integrated circuit. In recent years, MEMS techniques have been developed permitting the fabrication of various microscopic mechanical device structures on a single semi-conductor (e.g. silicon) chip, integrating mechanical functions with electronic signal processing. This integrated fabrication approach offers the potential for substantial reductions in device size and weight, as well as improvements in cost, performance and reliability for MEMS devices.

A variety of MEMS devices have been fabricated, including seismic activity measurement devices, micro-mirror positioning devices, and accelerometers. Accelerometers are widely used to control air bag deployment in automobiles. Accelerometers typically use a reference mass (i.e. a proof mass) that is supported by a flexure proximate to the body whose motion is to be measured. The motion of the reference mass with respect to the body is measured with a capacitive pick-off.

The formation of a capacitive MEMS accelerometer generally involves forming a first capacitive pick-off and a mass on a movable flexure proximate to a first semi-conductor wafer substrate or base, then bonding the first wafer to a second wafer bearing a second capacitive pick-off and related electronic control circuitry. The two wafers are typically connected via wire bonding between the sensing element and the capacitive pick-off. Such a configuration provides a variable capacitor wherein a change in capacitance due to movement of the flexure is used to determine the displacement of the mass relative to the accelerometer housing, yielding an acceleration of the accelerometer.

Such a capacitive MEMS accelerometer has several drawbacks, however. The relatively large parasitic capacitance of polysilicon tends to degrade performance of capacitive MEMS accelerometers fabricated on silicon wafers. Conventional capacitive MEMS accelerometers also frequently suffer from various drawbacks resulting from the capacitive sensing method, including deficiencies in sensitivity of the capacitive pick-off due to structural asymmetries, susceptibility to damage by impulsive shocks resulting from handling, and damage due to temperature-induced stresses. Because the two wafers must be bonded together to form a device and the distance between the two capacitive pick-offs may vary from one device to another, additional electronic circuitry is generally required to determine a base capacitance and “zero” each accelerometer. In addition, the need to wire bond two wafers together to form a single device takes up valuable device space, increases the number of manufacturing steps required to fabricate a device, adds to the cost of device fabrication, and potentially leads to a higher failure rate for capacitive accelerometers.

Accordingly, it is therefore desirable to providing for a low cost, easy to make and use, and enhanced sensitivity linear accelerometer that eliminates or reduces the drawbacks of prior known capacitive accelerometers. Thus, it would be highly desirable to fabricate a MEMS accelerometer on a single wafer. It would also be highly desirable to fabricate a MEMS accelerometer that does not exhibit the deficiencies associated with capacitive sensing. The art continues to search for improved MEMS accelerometers and methods of fabricating MEMS devices.

### SUMMARY

In general, the invention relates to micro-electro-mechanical systems, electronic devices, transducers and sensors, particularly magnetic MEMS devices such as accelerometers.

In one aspect, the invention provides a magnetic MEMS device including a base, a first member adjoined to the base, and a first magnetic field element proximate to the base and first member and having an altered output associated with movement of the first member. In some embodiments, the first member is at least one of a cantilever, a single beam, two parallel beams, two crossed beams or a membrane. In other embodiments, the first magnetic field element is at least one of a a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant magneto-impedence sensor and a tunneling giant magneto-resistive sensor.

In another aspect, the invention provides an electronic device including a substrate, a first member extending from the substrate, a first magnetic field element positioned proximate to the first member and structured to do at least one of emit or detect a magnetic field, and a second magnetic field element positioned proximate to the substrate and structured to do at least one of emit or detect a magnetic field, such that movement of the first member in a first direction by a non-magnetic force results in a variation of magnetic field strength associated with displacement in a first direction.

In certain preferred embodiments, the substrate or base includes one or more of the group consisting of silicon, silicon nitride, silicon carbide, silicon dioxide, metals and metal oxides. In other preferred embodiments, the electronic device includes at least one electronic circuit formed on or within the substrate and communicably adjoined to the first magnetic field emitter element and the first magnetic field detector element. In certain preferred embodiments, the electronic device includes at least one electronic circuit element selected from a power source, a pre-amplifier, a modulator, a demodulator, a filter, an analog to digital computer, a digital to analog converter, and a digital signal processor.

In another aspect, the invention provides a transducer including a substrate or base; a member extending from the substrate or base, a first magnetic field emitter element adjoining the substrate or base, and a first magnetic field detector element adjoining the substrate or base and positioned within a magnetic field of the magnetic field emitter element such that deflection of the member by a non-magnetic force results in a variation in output of the first magnetic field detector element.

In exemplary preferred embodiments of a magnetic MEMS device, the deflection of the member to produce a detectable variation in magnetic field strength at the first magnetic field detector element is calibrated to determine one or more of a displacement, a force, a pressure and an acceleration applied to the member. In some embodiments, the member is selected from the group consisting of a cantilever, a beam, two parallel beams, two crossed beams, and a membrane. In other embodiments, the first magnetic field emitter element is selected from at least one of a permanent magnet, a ferromagnetic material, a paramagnetic material, a solenoid, or an electromagnet. In other embodiments, the first magnetic field detector element is selected from at least one of magneto-electric, magneto-resistive, magneto-impedence, magneto-strictive, flux guided magneto-resistive, giant magnetic impedance, giant magneto-electric, giant magnetic-resistive, tunneling magneto-resistive or anisotropic magneto-resistive sensor.

In other exemplary embodiments, the first magnetic field detector element is positioned on the member, and the first magnetic field emitter element is positioned within a cavity defined by the substrate or base, the cavity being partially covered by the member. In certain preferred embodiments, the first magnetic field emitter element is positioned on the member, and the first magnetic field detector element is positioned within a cavity defined by the substrate or base, the cavity being partially covered by the member. In certain presently preferred embodiments, the transducer includes a second magnetic field detector element adjoining the substrate or base and positioned such that deflection of the member produces a detectable variation in magnetic field strength at one or both of the first and second magnetic field detector elements.

In still another aspect, the invention provides a sensor including a base, a first member extending from the base, and a first transducer means for sensing variation in a magnetic field, in which the variation of the magnetic field is related to movement of the first member. In one presently preferred aspect, the invention provides an accelerometer including a first emitter which transmits a magnetic flux and a first detector having an output which fluctuates when subjected to a magnetic flux, in which movement of the accelerometer results in variation of the output of the detector.

In a presently preferred aspect, the invention provides an accelerometer including a first emitter which transmits a magnetic flux and a first detector having an output that fluctuates when subjected to a magnetic flux, in which movement of the accelerometer results in variation of the output of the detector. In some exemplary embodiments, a single magnetic field detector element is used in combination with two or more magnetic field emitter elements. In certain preferred embodiments, a single magnetic field emitter element is used in combination with two or more magnetic field detector elements. In other preferred embodiments, the plurality of magnetic field detector elements is arranged on the substrate or base or the free end of the member in a two-dimensional planar array. In certain alternative embodiments, the plurality of magnetic field emitter elements is arranged on the substrate or base or the free end of the member in a two-dimensional planar array. In a presently preferred embodiment, the invention provides an accelerometer capable of multi-axis detection, preferably including a plurality of magnetic field emitter elements and/or magnetic field detector elements.

One feature of some embodiments of the present invention provides a magnetic MEMS system, transducer, electronic device, sensor or accelerometer fabricated on a single wafer. Another feature of some preferred embodiments of the present invention provides a low cost, easy to fabricate and more reliable linear accelerometer that eliminates or reduces the drawbacks of prior known capacitive accelerometers, including deficiencies in sensitivity of the capacitive pick-off due to structural asymmetries, impulsive shocks due to handling, and temperature-induced stresses. In other presently preferred embodiments, the present invention features a sensor having enhanced sensitivity in one or more axis corresponding to one or more dimensions of sensor movement.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

A fuller understanding of the present invention and the features and benefits thereof will be accomplished upon review of the following detailed description together with the accompanying drawings, in which:

FIGS. 1A-B are top and cross-sectional view diagrams illustrating one embodiment of an exemplary magnetic MEMS device using a cantilever member according to certain embodiments of the present invention.

FIGS. 2A-B are top and cross-sectional view diagrams illustrating one embodiment of an exemplary magnetic MEMS device using a cantilever member according to certain embodiments of the present invention.

FIGS. 3A-B are top and cross-sectional view diagrams illustrating one embodiment of an exemplary magnetic MEMS device using a cantilever member according to certain embodiments of the present invention.

FIGS. 4A-B are top and cross-sectional view diagrams illustrating one embodiment of an exemplary magnetic MEMS device using a cantilever member according to certain embodiments of the present invention.

FIGS. 5A-B are top and cross-sectional view diagrams illustrating one embodiment of an exemplary magnetic MEMS device using a cantilever member according to certain embodiments of the present invention.

FIGS. 6A-B are top and cross-sectional view diagrams illustrating one embodiment of an exemplary magnetic MEMS device using a single beam member according to certain embodiments of the present invention.

FIGS. 7A-B are top and cross-sectional view diagrams illustrating one embodiment of an exemplary magnetic MEMS device using a single beam member according to certain embodiments of the present invention.

FIGS. 8A-B are top and cross-sectional view diagrams illustrating one embodiment of an exemplary magnetic MEMS device using a single beam member according to certain embodiments of the present invention.

FIGS. 9A-B are top and cross-sectional view diagrams illustrating one embodiment of an exemplary magnetic MEMS device using a single beam member according to certain embodiments of the present invention.

FIGS. 10A-B are top and cross-sectional view diagrams illustrating an exemplary magnetic MEMS device using a membrane member according to certain embodiments of the present invention.

FIG. 11 is a cross-sectional side view illustrating an exemplary magnetic MEMS device using a cantilever member with a single magnetic field emitter element and a single magnetic field detector element according to certain embodiments of the present invention.

FIG. 12 is a cross-sectional side view illustrating an exemplary magnetic MEMS device using a beam or membrane member with a single magnetic field emitter element and a single magnetic field detector element according to certain embodiments of the present invention.

FIG. 13 is a perspective view illustrating an exemplary three-axis magnetic MEMS device using three substantially orthogonal cantilevers and three magnetic field emitter-magnetic detector pairs positioned for three-axis detection.

FIG. 14 is a perspective view illustrating an exemplary magnetic MEMS device capable of multi-axis detection using a cantilever member and including a plurality of magnetic field detector elements arranged in a two-dimensional planar array according to certain preferred embodiments of the present invention.

FIG. 15 is a perspective view illustrating another exemplary magnetic MEMS device capable of multi-axis detection using a cantilever member and including a plurality of magnetic field detector elements arranged in a two-dimensional planar array according to certain preferred embodiments of the present invention.

FIG. 16 is a cross-sectional side view illustrating an exemplary magnetic MEMS device capable of multi-axis detection using a beam structure and including a plurality of magnetic field detector elements according to certain preferred embodiments of the present invention.

FIG. 17 is a cross-sectional side view illustrating another exemplary magnetic MEMS device capable of multi-axis detection using a beam structure and including a plurality of magnetic field detector elements according to certain preferred embodiments of the present invention.

FIG. 18A, B, and C are top view diagrams illustrating an exemplary magnetic MEMS device capable of multi-axis detection using a crossed-beam structure and including a plurality of magnetic field elements according to certain preferred embodiments of the present invention.

FIG. 19 is a cross-sectional view diagram illustrating an exemplary magnetic MEMS cantilever device embodiment using a particular combination and arrangement of magnetic field elements according to certain preferred embodiments of the present invention.

FIG. 20 is a cross-sectional view diagram illustrating another exemplary magnetic MEMS cantilever device embodiment using a particular combination and arrangement of magnetic field elements according to certain preferred embodiments of the present invention.

FIG. 21 is a cross-sectional view diagram illustrating another exemplary magnetic MEMS cantilever device embodiment using a particular combination and arrangement of magnetic field elements according to certain preferred embodiments of the present invention.

FIG. 22 is a cross-sectional view diagram illustrating another exemplary magnetic MEMS cantilever device embodiment using a particular combination and arrangement of magnetic field elements according to certain preferred embodiments of the present invention.

FIG. 23 is a cross-sectional view diagram illustrating another exemplary magnetic MEMS cantilever device embodiment using a particular combination and arrangement of magnetic field elements according to certain preferred embodiments of the present invention.

FIG. 24 is a cross-sectional view diagram illustrating another exemplary magnetic MEMS cantilever device embodiment using a particular combination and arrangement of magnetic field elements according to certain preferred embodiments of the present invention.

FIG. 25 is a cross-sectional view block diagram illustrating an exemplary sequence of steps useful in practicing a photolithographic patterning, chemical vapor material depositing ion process to prepare exemplary magnetic MEMS structures on a substrate or base according to certain embodiments of the present invention.

FIG. 26 is a cross-sectional view block diagram illustrating an exemplary sequence of steps useful in practicing an electroplating material depositing ion process to prepare exemplary magnetic MEMS structures on a substrate or base according to certain embodiments of the present invention.

FIG. 27 is a cross-sectional view block diagram illustrating an exemplary selective material removal process useful in preparing exemplary magnetic MEMS structures on a substrate or base according to certain embodiments of the present invention.

FIG. 28 is a cross-sectional view block diagram illustrating another exemplary selective material removal process useful in preparing exemplary magnetic MEMS structures on a substrate or base according to certain embodiments of the present invention.

FIG. 29 is a cross-sectional view block diagram illustrating an exemplary sequential material depositing ion/selective material removal process useful in preparing exemplary magnetic MEMS structures on a substrate or base according to certain embodiments of the present invention.

FIG. 30 is a cross-sectional view block diagram illustrating another exemplary sequential material depositing ion/selective material removal process useful in preparing exemplary magnetic MEMS structures on a substrate or base according to certain embodiments of the present invention.

FIG. 31 is a cross-sectional view block diagram illustrating another exemplary sequential material depositing ion/selective material removal process useful in preparing exemplary magnetic MEMS structures on a substrate or base according to certain embodiments of the present invention.

FIGS. 32A-B are a combined perspective view, cross-sectional and top view block diagrams illustrating an exemplary process useful in preparing a magnetic MEMS device having a cantilever structure according to certain embodiments of the present invention.

FIGS. 33A-D are cross-sectional and top view block diagrams illustrating three alternative exemplary processes useful in preparing a magnetic MEMS device having a cantilever structure according to certain embodiments of the present invention.

FIGS. 34A-B are a combined perspective view, cross-sectional and top view block diagrams illustrating an exemplary process useful in preparing a magnetic MEMS device having a single beam structure according to certain embodiments of the present invention.

FIGS. 35A-C are cross-sectional and top view block diagrams illustrating three alternative exemplary processes useful in preparing a magnetic MEMS device having a single beam structure according to certain embodiments of the present invention.

FIGS. 36A-D are perspective view block diagrams illustrating an exemplary process useful in preparing a magnetic MEMS device having three cantilever structures and three magnetic field emitter-magnetic detector pairs positioned for three-axis detection.

FIGS. 37A-B are top view block diagrams illustrating an exemplary process for fabricating a magnetic field detector element on a substrate or base according to an embodiment of the present invention.

FIG. 38 is a cross-sectional and top view block diagram illustrating an exemplary process for fabricating a magnetic field emitter element on a substrate or base according to an embodiment of the present invention.

FIGS. 39A-B are perspective view block diagrams illustrating an exemplary process useful in preparing a magnetic MEMS device including a membrane.

### DETAILED DESCRIPTION OF THE PREFERRED EMBODIMENTS

The present invention will now be described, by way of example, with reference to the accompanying drawings. One skilled in the art will understand that certain features, shapes and positions of elements depicted in the figures can be altered or varied without conflicting with or deviating from the scope of the presently disclosed invention.

Exemplary Magnetic MEMS Device Structures

The present invention relates generally to magnetic MEMS devices, and particularly to magnetic MEMS accelerometers. Certain exemplary embodiments provide an accelerometer including a base, a first member adjoined to the base, and a first magnetic field element proximate to the base and first member and having an altered output associated with movement of the first member. Other exemplary embodiments provide a device including a member extending from a substrate or base; a first magnetic field emitter element adjoining the substrate or base; and a first magnetic field detector element also adjoining the substrate or base and positioned within the magnetic field of the magnetic field emitter element such that deflection of the member by a non-magnetic force produces a detectable variation in magnetic field strength at the first magnetic field detector element.

A number of magnetic MEMS devices can be prepared according to various embodiments of the present invention. Generally, these devices can be classified according to the number of independent directional axes for which the device can simultaneously detect a change in displacement or force. Single (one) axis magnetic MEMS devices can generally simultaneously detect a change in displacement or force in one dimension or direction. The multi-dimensional devices can generally simultaneously detect a change in displacement or force in more than one dimension or direction.

In addition, magnetic MEMS devices may be characterized in terms of the nature of the member, for example, single cantilever, single beam, membrane, multiple cantilever, dual parallel beam, dual crossed beam, and the like. One skilled in the art will understand that exemplary members may be structurally equivalent to flexures, suspension members, beams, combs and the like used in capacitive sensing devices. The present invention may also be characterized in terms of the number of magnetic field elements or magnetic field emitter/magnetic field detector pairs included in the transducer package.

Also, magnetic MEMS devices can be characterized by dimensions. Because the present invention utilizes wafer or MEMS fabrication techniques, the present invention can be of micron or sub-micron dimensions. For example, the dimensions of the magnetic field detector could be of the order of 1 micrometer squared or less, the size of the magnetic field emitter could be of the order of 1 micrometer squared or less, and the spacing between each could be also of the order of 1 micrometer or less. Of course, the present invention could be fabricated to larger dimensions, but the potential to create micron to sub-micron dimensions is achievable.

In some embodiments, the present invention may be used to determine the magnitude of an external non-magnetic force applied to the magnetic field element. Thus, the magnitude of the deflection or movement of the member resulting from application of an external non-magnetic force may be determined by detecting a variation in magnetic field at a magnetic field element. This magnitude of deflection or movement, combined with knowledge of the mass of the member, may be used to calculate the magnitude of the external non-magnetic force applied to the member. One skilled in the art understands that the present invention may have an effect on the magnitude of the external non-magnetic forces that the magnetic field element can detect.

Thus, for example, the shape, thickness, and material of construction of the present invention can affect the magnitude of the externally applied non-magnetic forces that the transducer can detect. Generally, membrane and beam structures are capable of measuring higher external non-magnetic forces applied to the present invention than comparable cantilever structures. In addition, thicker beam or cantilever structures are generally capable of measuring higher external non-magnetic forces applied to the present invention than comparable thinner structures. Moreover, higher modulus structures, for example those made from ceramic materials, are generally capable of measuring higher external non-magnetic forces applied to the present invention compared to lower modulus structure, for example, those made from metals or flexible polymers.

One or Two Axis Measurement Embodiments

FIGS. 1-12 illustrate various one or two axis structures according to certain embodiments of the present invention. Each of the illustrative embodiments pairs at least one magnetic field emitter element with at least one magnetic field detector element to form a magnetic field element pair. In some cases, a magnetic field emitter element is associated with more than one magnetic field detector element to form a magnetic field element system. It will be understood by one skilled in the art that the positions of the magnetic field emitter elements and magnetic field detector elements for a given magnetic field element pair or system may be exchanged to create additional embodiments not explicitly shown in the accompanying figures. For example, the positions of the magnetic field emitter elements and magnetic field detector elements for a given magnetic field element pair or system may be exchanged so that the emitter elements occupy positions previously occupied by the corresponding detector elements, and the detector elements occupy positions previously occupied by the corresponding emitter elements, thereby creating an alternate embodiment. It is intended that such alternate embodiments are included within the scope of the presently described invention.

It will be further understood that optional elements, such as optional masses or optional magnetic detector elements illustrated in some preferred embodiments, may also preferably be used in other illustrated embodiments to provide additional exemplary embodiments.

Single Cantilever Embodiments

FIGS. 1-5 are top (A) and cross-sectional (B) view diagrams illustrating exemplary magnetic MEMS devices using cantilever members according to certain embodiments of the present invention.

FIGS. 1A and 1B represent top and cross-sectional views, respectively, of a single cantilever, single axis embodiment including a substrate or base 100, a cantilever member 102 proximate to the substrate or base 100, a first magnetic field emitter element 104 proximate to the substrate or base 100 and adjoining the cantilever member 102, a first magnetic field detector element 106 proximate to the substrate or base 100 and positioned within a cavity 110 defined by the substrate or base 100 and within the magnetic field of the magnetic field emitter element such that deflection of the cantilever member 102 by a non-magnetic force results in a variation in output of the first magnetic field detector element 106. This embodiment also illustrates an optional mass 108 positioned on the cantilever member 102. Cantilever member 102 can be formed directly from the substrate or base 100 or can be deposited onto the substrate or base 100.

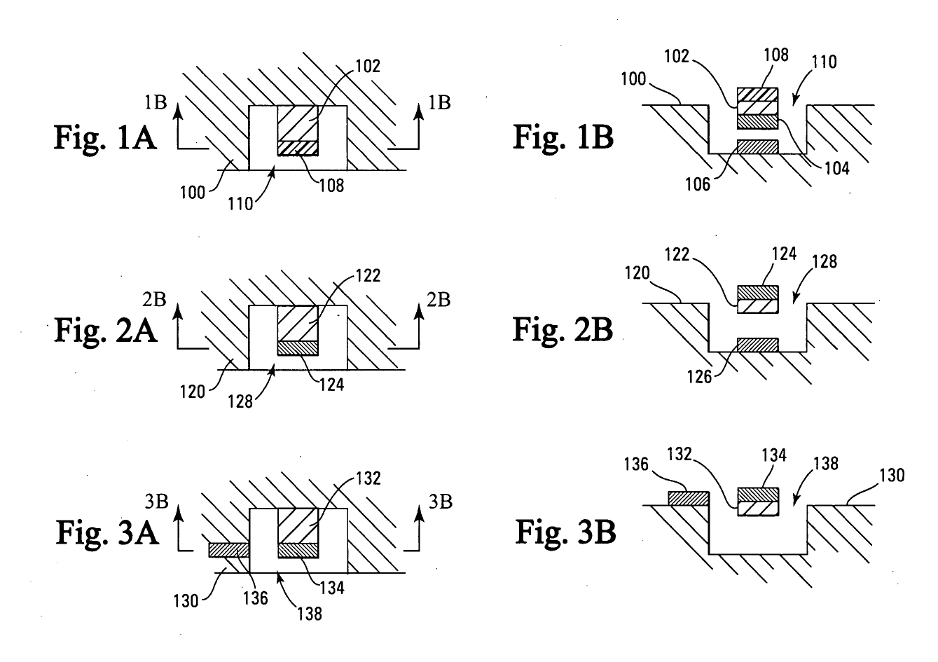

FIGS. 2A and 2B represent top and cross-sectional views, respectively, of an alternate single cantilever, single axis embodiment including a substrate or base 120, a cantilever member 122 proximate to the substrate or base 120, a first magnetic field emitter element 124 proximate to the substrate or base 120 and adjoining the cantilever member 122, and a first magnetic field detector element 126 proximate to the substrate or base 120 and positioned within a cavity 128 defined by the substrate or base 120 and within the magnetic field of the magnetic field emitter element 124 such that deflection of the cantilever member 122 by a non-magnetic force results in a variation in output of the first magnetic field detector element 126.

FIGS. 3A and 3B represent top and cross-sectional views, respectively, of another single cantilever, single axis embodiment including a substrate or base 130, a cantilever member 132 proximate to the substrate or base 130, a first magnetic field emitter element 134 proximate to the substrate or base 130 and adjoining the cantilever member 132, and a first magnetic field detector element 136 proximate to the substrate or base 130 and positioned adjacent to a cavity 138 and within the magnetic field of the magnetic field emitter element 134 such that deflection of the cantilever member 132 by a non-magnetic force results in a variation in output of the first magnetic field detector element 136.

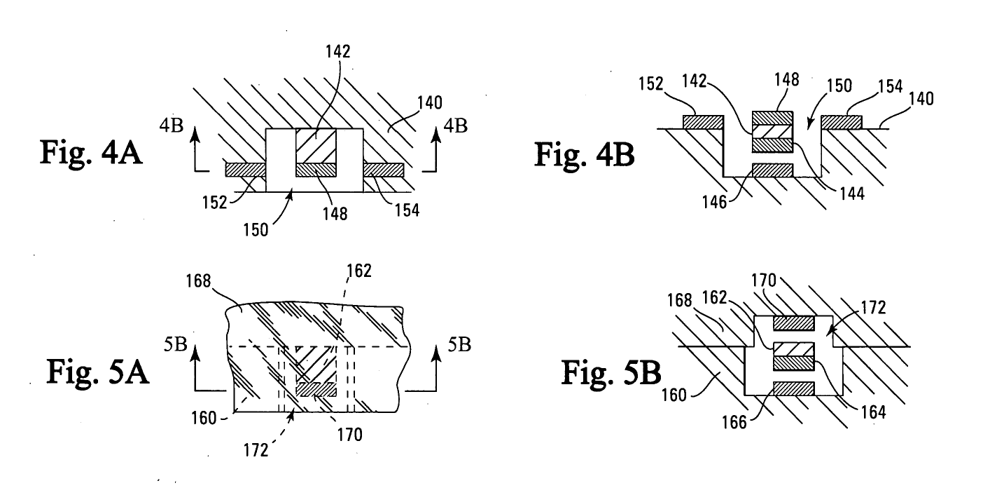

FIGS. 4A and 4B represent top and cross-sectional views, respectively, of an additional single cantilever, two axis embodiment including a substrate or base 140, a cantilever member 142 proximate to the substrate or base 140, a first magnetic field emitter element 144 proximate to the substrate or base 140 and adjoining the cantilever member 142, a first magnetic field detector element 146 proximate to the substrate or base and positioned within a cavity 150 defined by the substrate or base 140 and within the magnetic field of the first magnetic field emitter element 144 such that deflection of the cantilever member 142 by a non-magnetic force results in a variation in output of the first magnetic field detector element 146.

This embodiment also includes an optional second magnetic field emitter element 148 proximate to the substrate or base 140 and adjoining the cantilever member 142, an optional second magnetic field detector element 152 and an optional third magnetic field detector element 154 positioned within the magnetic field of the second magnetic field emitter element 148 adjacent to the cavity 150 defined by the substrate or base 140, such that deflection of the cantilever member 142 by a non-magnetic force produces a detectable variation in magnetic field strength at one or both of the second magnetic field detector element 152 and third magnetic field detector element 154. This embodiment, with all optional elements included, illustrates a magnetic field element capable of measuring a displacement or force over a wide dynamic range in two different dimensions simultaneously.

FIGS. 5A and 5B represent top and cross-sectional views, respectively, of an additional single cantilever, single axis embodiment including a first substrate or base 160, a cantilever member 162 proximate to the first substrate or base 160, a first magnetic field emitter element 164 proximate to the first substrate or base 160 through the cantilever member 162, a first magnetic field detector element 166 proximate to the first substrate or base 160, a second substrate or base 168 bearing a second magnetic field detector element 170 and attached to the first substrate or base 160 to form a cavity 172, wherein one or both of the first magnetic field detector element 166 and second magnetic field detector element 170 is positioned within the magnetic field of the first magnetic field emitter element 164 such that deflection of the cantilever member 162 by a non-magnetic force produces a detectable variation in magnetic field strength at one or both of the first magnetic field detector element 166 and second magnetic field detector element 170. This embodiment illustrates a device that in some preferred embodiments is capable of measuring a displacement or force in a single dimension over a wide dynamic range or with high sensitivity.

Single Beam Embodiments

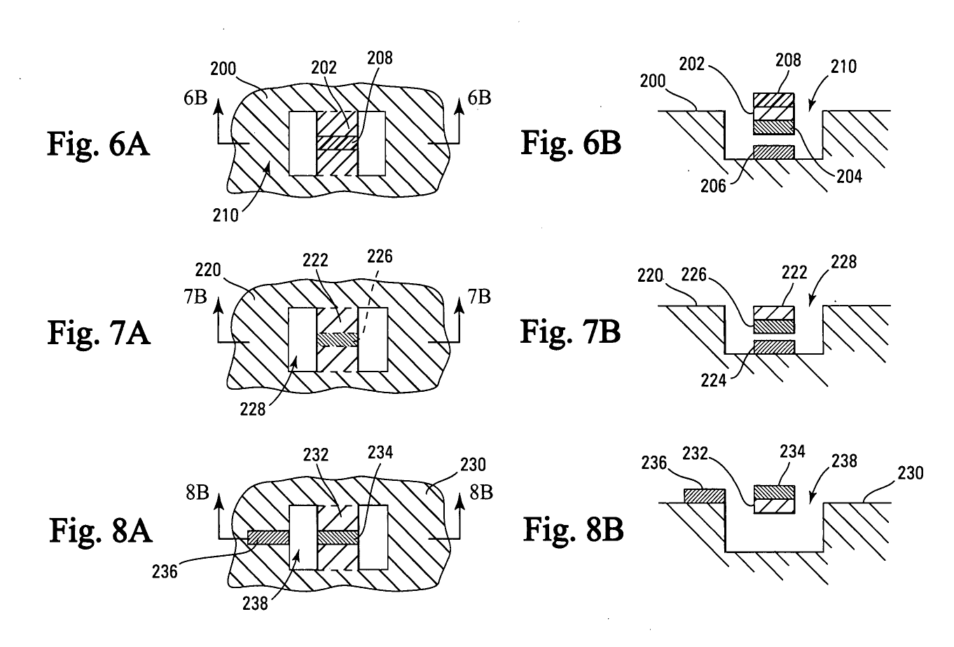

FIGS. 6-9 are top (A) and cross-sectional (B) view diagram illustrating exemplary magnetic MEMS devices using single beam members according to certain embodiments of the present invention.

FIGS. 6A and 6B represent top and cross-sectional views, respectively, of a single beam, single axis embodiment including a substrate or base 200, a beam member 202 proximate to and connected to the substrate or base 200 at both ends of the beam member 202, a first magnetic field emitter element 204 proximate to the substrate or base 200 and adjoining the beam member 202, a first magnetic field detector element 206 proximate to the substrate or base 200 and positioned within a cavity 210 defined by the substrate or base 200 and within the magnetic field of the magnetic field emitter element 204 such that deflection of the beam member 202 by a non-magnetic force results in a variation in output of the first magnetic field detector element 206. This embodiment also illustrates an optional mass 208 positioned on the cantilever member 202.

FIGS. 7A and 7B represent top and cross-sectional views, respectively, of a single beam, single axis embodiment including a substrate or base 220, a beam member 222 proximate to and connected with the substrate or base 220 at both ends of the beam member 222, a first magnetic field emitter element 226 proximate to the substrate or base 220 and adjoining the beam member 222, and a first magnetic field detector element 224 proximate to the substrate or base 220 and positioned within a cavity 228 defined by the substrate or base 220 and within the magnetic field of the magnetic field emitter element 226 such that deflection of the beam member 222 by a non-magnetic force results in a variation in output of the first magnetic field detector element 224.

FIGS. 8A and 8B represent top and cross-sectional views, respectively, of a single beam, single axis embodiment including a substrate or base 230, a beam member 232 proximate to and connected to the substrate or base 230 at both ends of the beam member 232, a first magnetic field emitter element 234 proximate to the substrate or base 230 and adjoining the beam member 232, and a first magnetic field detector element 236 proximate to the substrate or base 230 and positioned adjacent to a cavity 238 defined by the substrate or base 230 and within the magnetic field of the magnetic field emitter element 234 such that deflection of the beam member 232 by a non-magnetic force results in a variation in output of the first magnetic field detector element 236.

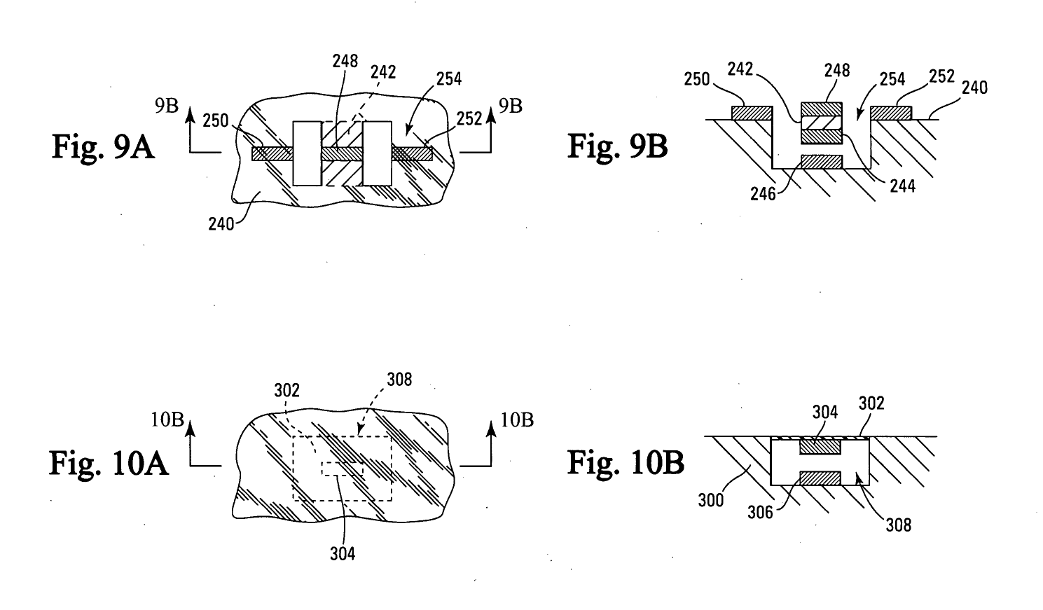

FIGS. 9A and 9B represent top and cross-sectional views, respectively, of a single beam, two-axis embodiment including a substrate or base 240, a beam member 242 proximate to and connected to the substrate or base 240 at both ends of the beam member 242, a first magnetic field emitter element 244 proximate to the substrate or base 240 and adjoining the beam member 242, a first magnetic field detector element 246 proximate to the substrate or base 240 and positioned within a cavity 254 defined by the substrate or base 240 such that deflection of the beam member 242 in a first direction by a non-magnetic force results in a variation in output of the first magnetic field detector element 246, and a second magnetic field emitter element 248 proximate to the substrate or base 240 and adjoining the beam member 242, a second magnetic field detector element 250 proximate to the substrate or base 240 and positioned adjacent to the cavity 254 defined by the substrate or base 240, and an optional third magnetic field detector element 252 proximate to the substrate or base 240 and positioned adjacent to the cavity 254 defined by the substrate or base 240, such that deflection of the beam member 242 in a second direction produces a detectable variation in magnetic field strength at one or both of the second magnetic field detector element 250 and optional third magnetic field detector element 252.

Membrane Embodiments

FIGS. 10A and 10B represent top and cross-sectional views, respectively, of a single membrane, single axis embodiment including a substrate or base 300, a membrane member 302 proximate to and connected to the substrate or base 300 at all edges of the membrane member 302, a first magnetic field emitter element 304 proximate to the substrate or base 300 and adjoining the membrane member 302, a first magnetic field detector element 306 proximate to the substrate or base 300 and positioned within a cavity 308 defined by the substrate or base 300 and within the magnetic field of the magnetic field emitter element 304 such that deflection of the membrane member 302 by a non-magnetic force results in a variation in output of the first magnetic field detector element 306. This embodiment illustrates a device that in some preferred embodiments is capable of measuring an integrated applied force per unit area of the membrane surface.

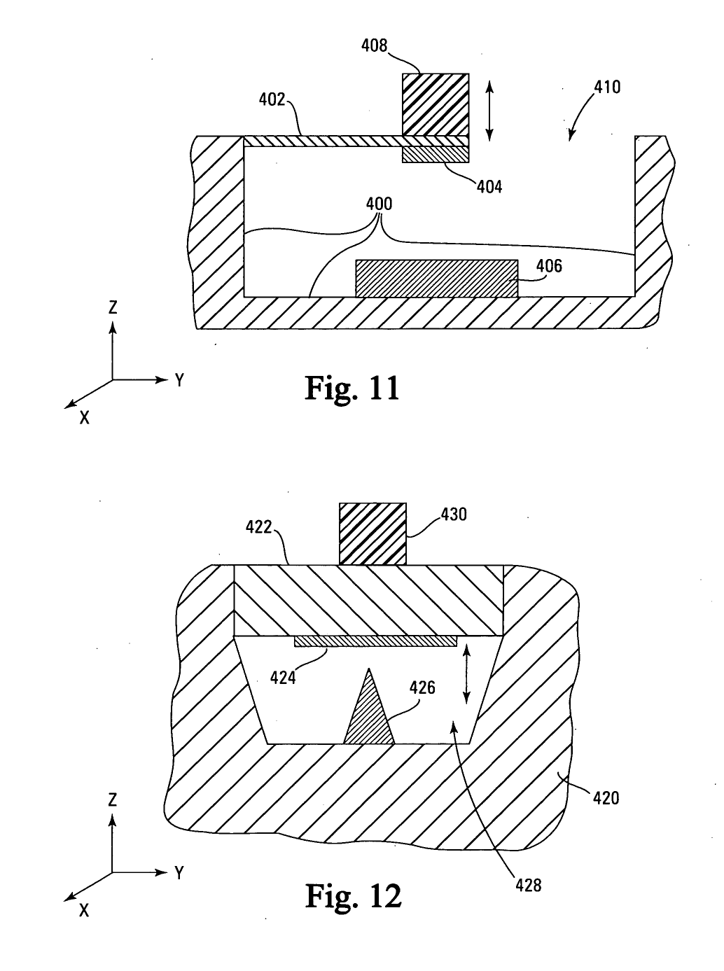

FIG. 11 is a cross-sectional side view illustrating an exemplary magnetic MEMS device using a cantilever member with a single magnetic field emitter element and a single magnetic field detector element according to certain embodiments of the present invention. FIGS. 11 illustrates a single cantilever, single axis embodiment including a substrate or base 400, a cantilever member 402 proximate to the substrate or base 400, a first magnetic field emitter element 404 proximate to the substrate or base 400 and adjoining the cantilever member 402, a first magnetic field detector element 406 proximate to the substrate or base 400 and positioned within a cavity 410 defined by the substrate or base 400 and within the magnetic field of the magnetic field emitter element 404 such that deflection of the cantilever member 402 by a non-magnetic force results in a variation in output of the first magnetic field detector element 406. This embodiment is illustrated with an optional mass 408 positioned on the cantilever member 402.

FIG. 12 is a cross-sectional side view illustrating an exemplary magnetic MEMS device using a beam or membrane member with a single magnetic field emitter element and a single magnetic field detector element according to certain embodiments of the present invention. FIGS. 12 illustrates a single beam or membrane, single axis embodiment including a substrate or base 420, a beam member 422 proximate to and connected to the substrate or base 420 at both ends of the beam member 422, a first magnetic field emitter element 424 proximate to the substrate or base 420 and adjoining the beam member 422, a first magnetic field detector element 426 proximate to the substrate or base 420 and positioned within a cavity 428 defined by the substrate or base 420 and within the detection range of the magnetic field emitter element 424 such that deflection of the beam member 422 by a non-magnetic force results in a variation in output of the first magnetic field detector element 426. This embodiment is illustrated with an optional mass 430 positioned on the beam member 422.

Three Axis Measurement Embodiments

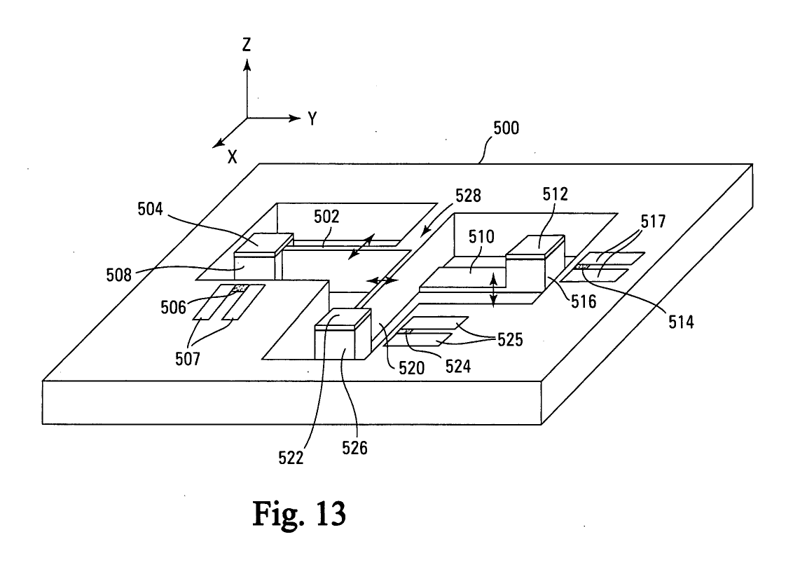

FIGS. 13-18 illustrate various three-axis magnetic MEMS devices according to certain embodiments of the present invention. Each of the illustrative embodiments uses at least one magnetic field emitter element with at least two magnetic field detector elements, or at least one magnetic field detector element with at least two magnetic field emitter elements, to form a pair of magnetic field elements, hereafter referred to as a magnetic field element pair. In some cases, a magnetic field emitter element is associated with more than one magnetic field detector element to form a magnetic field element system.

It will be understood by one skilled in the art that the positions of the magnetic field emitter elements and magnetic field detector elements for a given magnetic field element pair or system may be exchanged to create additional embodiments not explicitly shown in the accompanying figures. For example, the positions of the magnetic field emitter elements and magnetic field detector elements for a given magnetic field element pair or system may be exchanged so that the all emitter elements occupy positions previously occupied by detector elements, and all detector elements occupy positions previously occupied by emitter elements, thereby creating an alternate embodiment. It is intended that such alternate embodiments are included within the scope of the presently described invention.

It will be further understood that optional elements, such as optional masses or optional magnetic detector elements illustrated in some preferred embodiments, may also preferably be used in other illustrated embodiments to provide additional exemplary embodiments.

Three Cantilever Embodiment with Three Magnetic Field Emitter/Detector Pairs

FIG. 13 is a perspective view illustrating a preferred three-axis magnetic MEMS device using three substantially orthogonal cantilever members and three magnetic field emitter-magnetic field detector pairs to form a system of magnetic field elements according to an embodiment of the present invention. As used throughout this disclosure, substantially orthogonal means that the members are preferably positioned at substantially right angles oriented 90° with respect to each other, defining a rectangular coordinate system. However, in other embodiments, the members may be positioned at angles other than 90°, for example, at acute or obtuse angles. Such embodiments may be preferred for embodiments useful in defining motion relative to a non-rectangular coordinate system, for example, a spherical coordinate system.

According to one preferred embodiment, the three-axis magnetic MEMS device includes a substrate or base 500 defining a cavity 528, a first cantilever member 502 having a free end distal from a connected end, the connected end proximate to the substrate or base 500 and the free end proximate to a first magnetic field element 504 positioned to at least partially cover the cavity 528. The device also includes a second cantilever member 510 substantially orthogonal to the first member 502, having a free end distal from a connected end, the connected end proximate to the substrate or base 500 and the free end proximate to a second magnetic field element 512 positioned to at least partially cover the cavity 528. The device further includes a third cantilever member 520 substantially orthogonal to the first cantilever member 502 and the second cantilever member 510, having a free end distal from a connected end, the connected end proximate to the substrate or base 500 and the free end proximate to a third magnetic field element 522 positioned to at least partially cover the cavity 528. The device further includes a fourth magnetic field element 506 adjoining the substrate or base 500 and positioned to detect or emit a magnetic field associated with the first magnetic field element 504 such that deflection of the free end of the first cantilever member 502 produces a detectable variation in magnetic field strength corresponding to displacement in a first direction. The device also includes a fifth magnetic field element 514 adjoining the substrate or base 500 and positioned to detect or emit a magnetic field associated with the second magnetic field element 512 such that deflection of the free end of the second cantilever member 510 produces a detectable variation in magnetic field strength corresponding to displacement in a second direction substantially orthogonal to the first direction. The device additionally includes a sixth magnetic field element 524 adjoining the substrate or base 500 and positioned to detect or emit a magnetic field associated with the third magnetic field element 522 such that deflection of the free end of the third cantilever member 520 produces a detectable variation in magnetic field strength corresponding to displacement in a third direction substantially orthogonal to the first and second directions. Each of the magnetic field elements 506, 514 and 524 have conductive leads 507, 517 and 525 to provide and communicate an electrical signal.

Optionally, the exemplary three-axis device includes a first mass 508 attached to (or formed integral with) the free end of the first cantilever member 502, a second mass 516 attached to (or formed integral with) the free end of the second cantilever member 510, and a third mass 526 attached to (or formed integral with) the free end of the third cantilever member 520.

Single Cantilever Embodiment with Array of Magnetic Field Elements

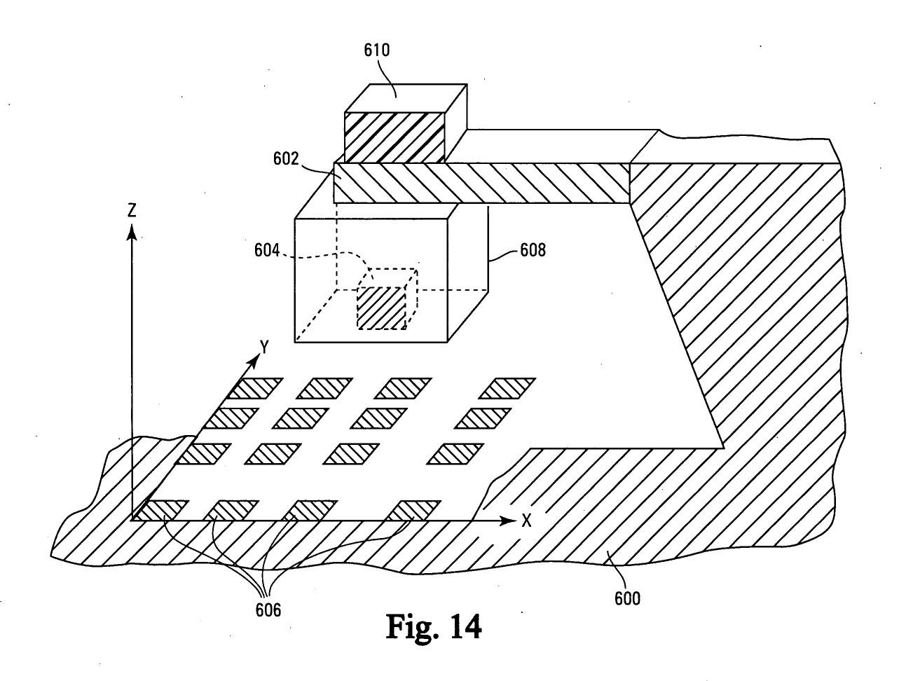

FIG. 14 is a perspective view illustrating exemplary magnetic MEMS devices capable of multi-axis detection using a cantilever structure and including a plurality of magnetic field elements arranged in a two-dimensional planar array according to certain preferred embodiments of the present invention.

FIG. 14 illustrates a single cantilever, multi-axis embodiment including a substrate or base 600, a cantilever member 602 proximate to the substrate or base, a first magnetic field emitter element 604 proximate to the substrate or base 600 and adjoining the cantilever member 602, a plurality of magnetic field detector elements 606 proximate to the substrate or base 600 and arranged to form a two-dimensional planar array wherein one or more of the plurality of magnetic field detector elements 606 is positioned within the magnetic field of the first magnetic field emitter element 604, such that deflection of the cantilever member 602 by a non-magnetic force produces a detectable variation in magnetic field strength at one or more of the plurality of magnetic field detector elements 606.

FIG. 14 also illustrates two optional masses, the first optional mass 608 proximate to but positioned below the cantilever member 602, and the second optional mass 610 proximate to but positioned above the cantilever member 602. Typically, only one of the optional masses would be used, although in some embodiments, both masses may be present.

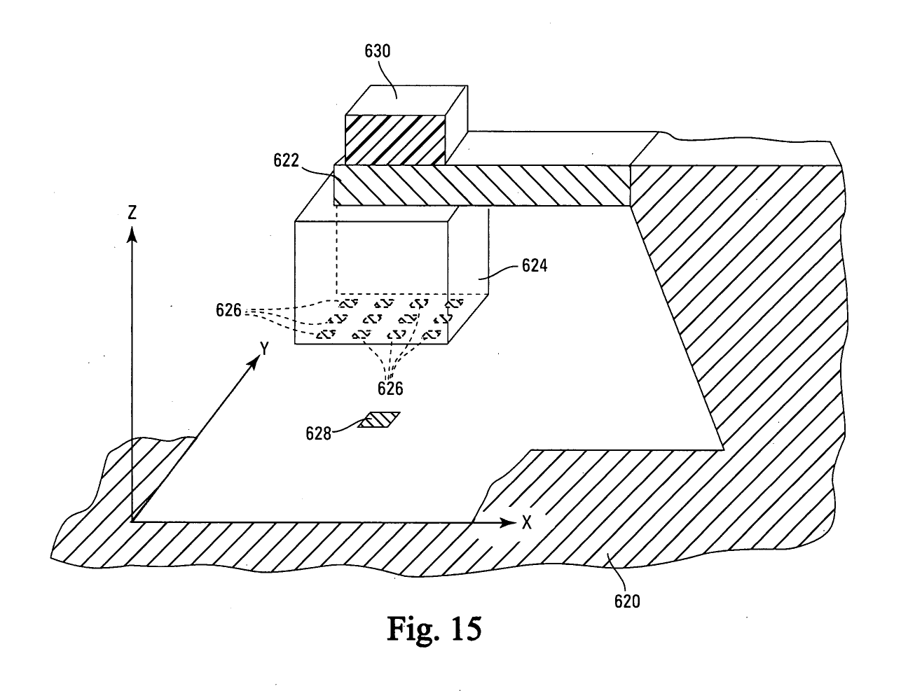

FIG. 15 illustrates an alternative single cantilever, multi-axis embodiment including a substrate or base 620, a cantilever member 622 proximate to the substrate or base 620, a plurality of magnetic field detector elements 626 proximate to the substrate or base 620 and adjoining the cantilever member 622 and arranged to form a two-dimensional planar array, and a first magnetic field emitter element 628 proximate to the substrate or base 620 and positioned such that one or more of the plurality of magnetic field detector elements 626 lies within the magnetic field of the first magnetic field emitter element 628, such that deflection of the cantilever member 622 by a non-magnetic force produces a detectable variation in magnetic field strength at one or more of the plurality of magnetic field detector elements 626.

FIG. 15 also illustrates two optional masses, the first optional mass 624 proximate to but positioned below the cantilever member 622, and the second optional mass 630 proximate to but positioned above the cantilever member 622. Generally, only one of the optional masses would be used, although in some embodiments, both masses may be present.

Single or Dual Parallel Beam Embodiment with Plurality of Magnetic Field Elements

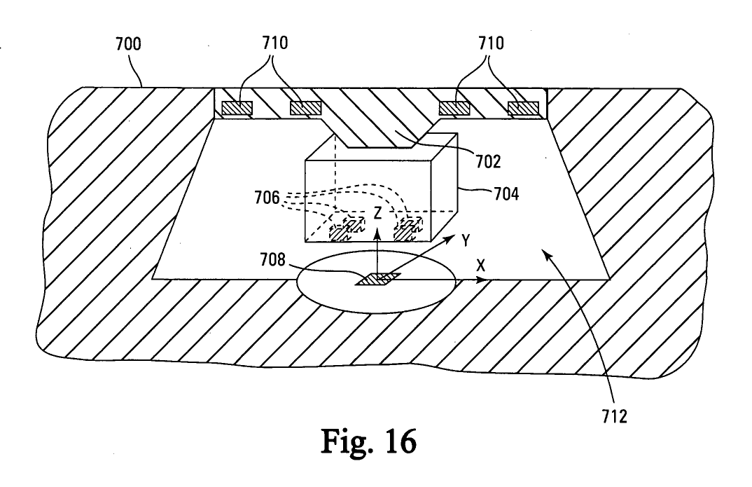

FIG. 16 is a cross-sectional side view illustrating exemplary magnetic MEMS devices capable of multi-axis detection using a single or dual parallel beam structure and including a plurality of magnetic field elements according to certain preferred embodiments of the present invention.

FIG. 16 illustrates a single beam or dual parallel beam, multi-axis embodiment including a substrate or base 700, one (or two parallel) beam member 702, proximate to and adjoining the substrate 700 at both ends of the beam member 702, a plurality of magnetic field detector elements 706 proximate to the substrate or base 700 and adjoining the beam member (or two parallel beam members) 702 and arranged to form a two-dimensional planar array, and a first magnetic field emitter element 708 proximate to the substrate or base 700 within a cavity 712 defined by the substrate or base 700 and positioned such that one or more of the plurality of magnetic field detector elements 706 lies within the magnetic field of the first magnetic field emitter element 708, such that deflection of the beam member (or two parallel beam members) 702 by a non-magnetic force produces a detectable variation in magnetic field strength at one or more of the plurality of magnetic field detector elements 706.

FIG. 16 also illustrates an optional plurality of magnetic field elements 710 (e.g. magneto-strictive elements) positioned on or within the deflectable beam member (or two parallel beam members) 622 and capable of producing a change in electrical output in response to a bending or movement of the beam member (or two parallel beam members) 702 in response to an applied non-magnetic force.

This embodiment illustrates a magnetic MEMS device that in some preferred embodiments is capable of measuring a displacement or force in multiple dimensions with high sensitivity, and which, in some embodiments, can endure high force loads without degrading performance of the device.

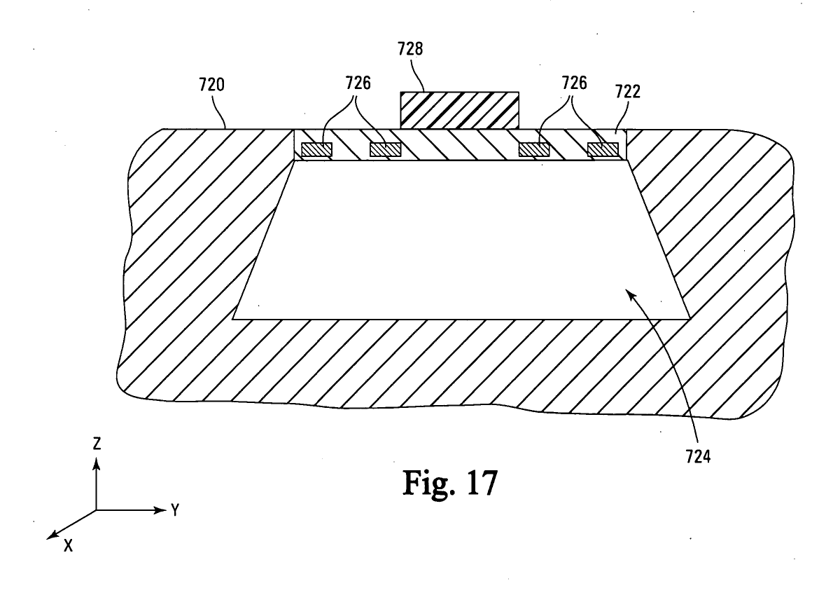

FIG. 17 illustrates another embodiment of a single beam or dual parallel beam, multi-axis embodiment including a substrate or base 720, one (or two parallel) beam member 722 proximate to the substrate or base 720, proximate to and connected to the substrate 720 at both ends of the beam member 722, a plurality of magnetic field elements 726 proximate to the substrate or base and adjoining the beam member (or two parallel beam members) 722, positioned within the deflectable beam member (or two parallel beam members) 722 and capable of producing a change in electrical output in response to a bending or movement of the beam member (or two parallel beam members) 722 in response to an applied non-magnetic force. FIG. 17 also illustrates an optional mass 728 positioned on a surface of the beam member (or two parallel beam members) 722.

This embodiment illustrates a magnetic MEMS device that in some preferred embodiments is capable of measuring a displacement or force in multiple dimensions, and which, in some embodiments, can endure extremely high force loads without degrading performance of the device.

Dual Crossed Beam Embodiment with Plurality of Magnetic Field Elements

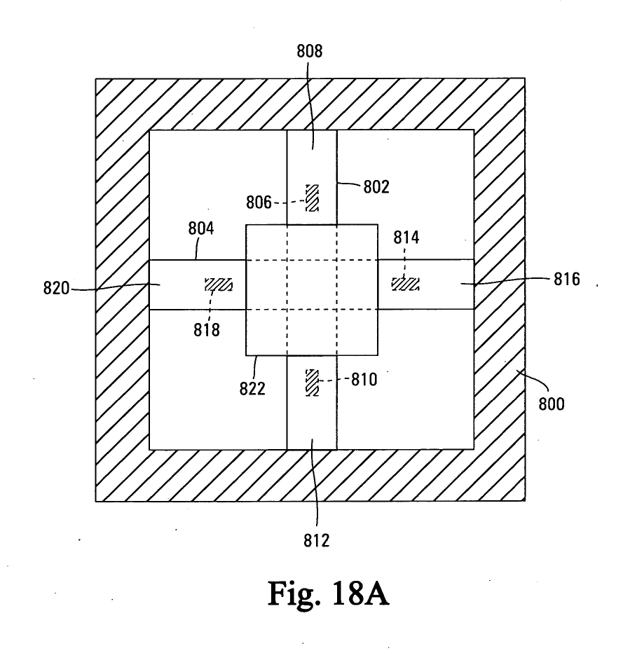

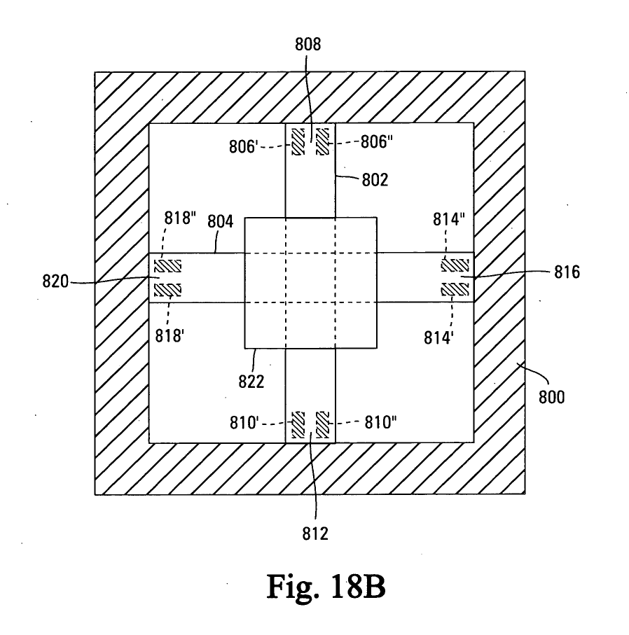

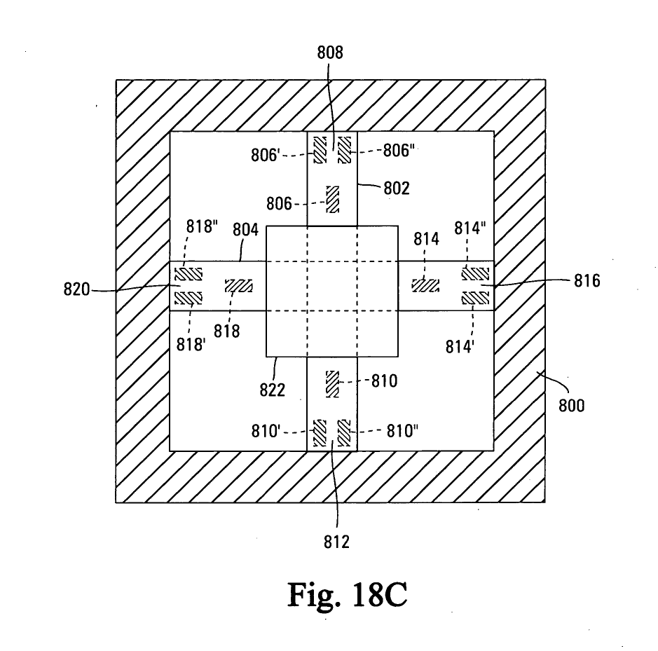

FIGS. 18A-C are a top view diagrams illustrating an exemplary magnetic MEMS device capable of multi-axis detection using a crossed-beam structure and including a plurality of magnetic field elements according to certain preferred embodiments of the present invention.

FIG. 18A illustrates a dual crossed beam, multi-axis embodiment including a substrate or base 800, a first beam member 802 connected to the substrate or base 800 at both ends of the first beam member 802, and a second beam member 804 crossing and substantially orthogonal to the first beam member 802, and proximate to the substrate or base at both ends. Further, first beam member 802 has a first side 808 and second side 812, and second beam member 804 has a first side 816 and a second side 820. This embodiment includes a first magnetic field element 806 positioned in the first side 808 of first beam member 802, a second magnetic field element 810 positioned in the second side 812 of first beam member 802, a third magnetic field element 814 positioned in the first side 816 of second beam member 804, and a fourth magnetic field element 818 positioned in the second side 820 of second beam member 804. In this embodiment, magnetic field elements 806, 810, 814 and 818 are preferably magneto-strictive elements capable of producing a change in electrical output in response to a bending or movement of the beam members 802 and/or 804 in response to an applied non-magnetic force. Because the magnetic field elements are positioned proximate mass 822, they will be more apt to detect movement in a z-axis (up and down). Therefore, this embodiment is best suited for one axis detection.

FIG. 18B illustrates a dual crossed beam, multi-axis embodiment the same as in FIG. 18A, with the exception that each side of beam members 802 and 804 include two magnetic field elements (806′ and 806″; 810′ and 810″; 814′ and 814″; 818′ and 818″). In this embodiment, magnetic field elements 806′, 806″, 810′, 810″, 814′, 814″, 818′ and 818″ are preferably magneto-strictive elements capable of producing a change in electrical output in response to a bending or movement of the beam members 802 and/or 804 in response to an applied non-magnetic force. Because the magnetic field elements are positioned proximate substrate or base 800, they will be more apt to detect movement (either twisting or movement from side to side) in a x-axis (corresponding to elements on the first member 802), or in a y-axis (corresponding to elements on the second member 804). Therefore, this embodiment is best suited for two axis detection.

FIG. 18C illustrates a dual crossed beam, multi-axis embodiment the same as in FIGS. 18A and B, with the exception that each side of beam members 802 and 804 include three magnetic field elements (806, 806′ and 806″; 810, 810′ and 810″; 814, 814′ and 814″; 818, 818′ and 818″). In this embodiment, each of the magnetic field elements 806, 806′, 806″, 810, 810′, 810″, 814, 814′, 814″, 818, 818′ and 818″ are preferably magneto-strictive elements capable of producing a change in electrical output in response to a bending or movement of the beam members 802 and/or 804 in response to an applied non-magnetic force. Because this embodiment includes elements to measure movement in the x-axis (806′, 806″, 810′ and 810″), the y-axis (814′, 814″, 818′, 818″) and the z-axis (806, 810, 814, and 818), this embodiment is capable of three axis detection. It is also contemplated that for this embodiment (and the embodiments in FIGS. 18A and B), that each element corresponding to the axis it is detecting could be connected to form a wheatstone bridge. For example, elements 806, 810, 814 and 818 could be connected to form a wheatstone bridge, which collectively would detect movement in a z-axis. Also, each embodiment in FIGS. 18A-C illustrates an optional mass 822 proximate to one or both of the first beam member 802 and second beam member 804.

This embodiment illustrates a magnetic MEMS device that in some preferred embodiments is capable of measuring a linear or angular displacement, force, or acceleration in three or more dimensions over a wide dynamic range or with high sensitivity.

Magnetic Field Elements

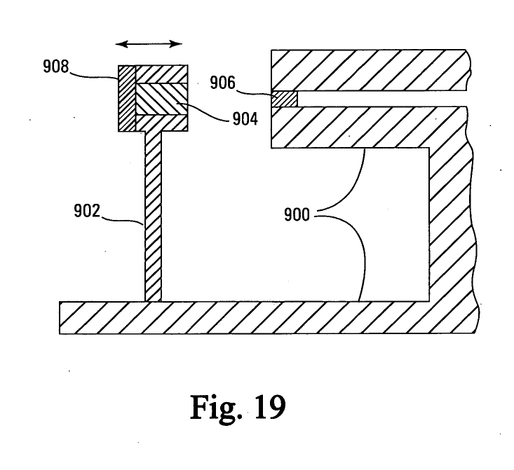

FIGS. 19-24 are cross-sectional view diagrams illustrating exemplary magnetic MEMS single cantilever embodiments using various combinations of magnetic field elements according to certain preferred embodiments of the present invention. It will be understood by one skilled in the art that the exemplary magnetic field elements may be used with other types of members, including, but not limited to, multiple cantilever systems, single beam members, membrane members, dual parallel beam members, dual crossed beam members, and the like without departing from the present invention.

It is further understood that each of the illustrative embodiments pairs at least one magnetic field emitter element with at least one magnetic field detector element to form a magnetic field element pair. In some cases, a magnetic field emitter element is associated with more than one magnetic field detector element to form a magnetic field element system. It will be understood by one skilled in the art that the positions of the magnetic field emitter elements and magnetic field detector elements for a given magnetic field element pair or system may be exchanged to create additional embodiments not explicitly shown in the accompanying figures. For example, the positions of the magnetic field emitter elements and magnetic field detector elements for a given magnetic field element pair or system may be exchanged so that the all emitter elements occupy positions previously occupied by detector elements, and all detector elements occupy positions previously occupied by emitter elements, thereby creating an alternate embodiment. It is intended that such alternate embodiments are included within the scope of the presently described invention.

FIG. 19 illustrates a cross-sectional side view of a single cantilever, single axis embodiment including a substrate or base 900, a cantilever member 902 proximate to the substrate or base 900, a first magnetic field emitter element 904 proximate to the substrate or base 900 and adjoining the cantilever member 902, a first magnetic field detector element 906 proximate to the substrate or base 900 and positioned within the magnetic field of the magnetic field emitter element 904 such that deflection of the cantilever member 902 by a non-magnetic force results in a variation in output of the first magnetic field detector element 906. This embodiment also illustrates an optional mass 908 positioned on the cantilever member 902.

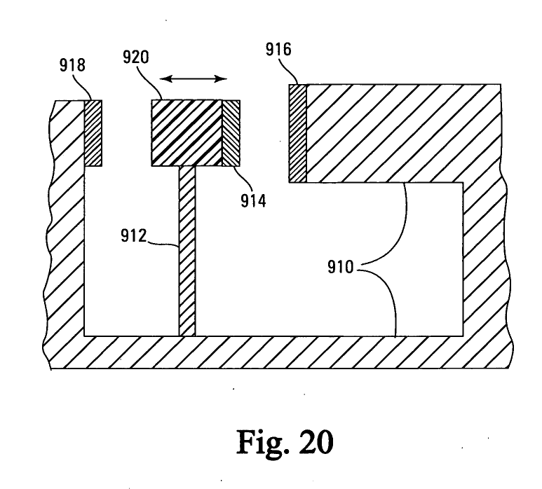

FIG. 20 illustrates a cross-sectional side view of a single cantilever, single axis embodiment including a substrate or base 910, a cantilever member 912 proximate to the substrate or base 910, a first magnetic field emitter element 914 proximate to the substrate or base 910 and adjoining the cantilever member 912, a first magnetic field detector element 916 proximate to the substrate or base 910, a second magnetic field detector element 918 proximate to the substrate or base 910, wherein one or both of the first magnetic field detector element 916 and second magnetic field detector element 918 lies within the magnetic field of the magnetic field emitter element 914 such that deflection of the cantilever member 912 by a non-magnetic force produces a detectable variation in magnetic field strength at one or both of the first magnetic field detector element 916 and the second magnetic field detector element 918. FIG. 20 also illustrates an optional mass 920 positioned on the cantilever member 912.

This embodiment illustrates a magnetic MEMS device that in some preferred embodiments is capable of measuring a displacement or force in a single dimension over a wide dynamic range or with high sensitivity.

Magnetic Field Emitter Element Embodiments

Various functional elements may be used to provide a magnetic field emitter. Preferably, the magnetic field emitter element is a material that emits a magnetic field. The magnetic field emitter can be selected from, but is not limited to, a permanent magnet (PM), a ferromagnetic material, a paramagnetic material, a solenoid, or an electromagnet. These emitters are preferred because each has an intrinsic magnetic property. Intrinsic, in relation to these emitters, means that the field emitted is not based on the movement of the emitter itself. Having an intrinsic magnetic moment is advantageous because it limits the variables needed to calculate the output of the magnetic field detector and hence increases the measurement reliability and functionality of the device. For embodiments that use a permanent magnet, the magnetization direction can be set either in plane or out of plane, with respect to the detector element. In some preferred embodiments of an electromagnet, a coil is provided through which is passed an electrical current to create an electromagnetic field. In other preferred embodiments of a solenoid, the coil surrounds a magnetic core, and an electrical current is passed through the coil to create an electromagnetic field. The coil may be formed, for example, by electroplating the coil structure on the substrate or base, by winding metal wire to form a coil on the substrate or base, or by depositing a flexible circuit element on the substrate or base. For example, the coil assembly may be deposited using a pick and place technique known to those skilled in the art of magnetic read/write head fabrication.

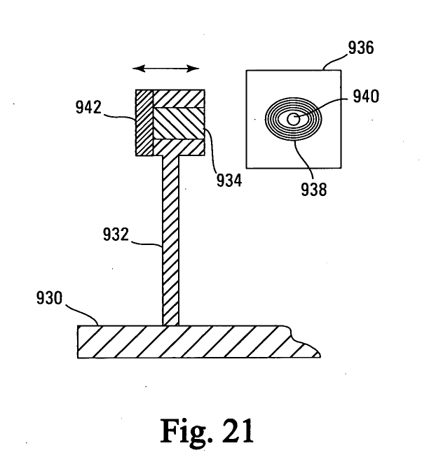

FIG. 21 illustrates a cross-sectional side view of a single cantilever, single axis embodiment including a substrate or base 930, a cantilever member 932 proximate to the substrate or base 930, a first magnetic field detector element 934 proximate to the substrate or base 930 and adjoining the cantilever member 932, a first magnetic field emitter element 936 including an electro-magnet comprising a magnetic core 940 and an inductor (e.g. a cylindrical coil) 938, proximate to the substrate or base 930 and positioned within the detection range of the magnetic field detector element 934 such that deflection of the cantilever member 932 by a non-magnetic force results in a variation in output of the first magnetic field detector element 934. This embodiment also illustrates an optional mass 942 positioned on the cantilever member 932.

Magnetic Field Detector Element Embodiments

Various functional elements may be used to provide a magnetic field detector. Preferably, the magnetic field detector element is an element that is capable of detecting a magnetic field. A magnetic field detector can be selected from, but is not limited to, a magneto-electric, magneto-resistive, magneto-impedence, magneto-strictive, flux guided magneto-resistive, giant magnetic impedance, giant magneto-electric, giant magnetic-resistive, tunneling magneto-resistive or anisotropic magneto-resistive sensor.

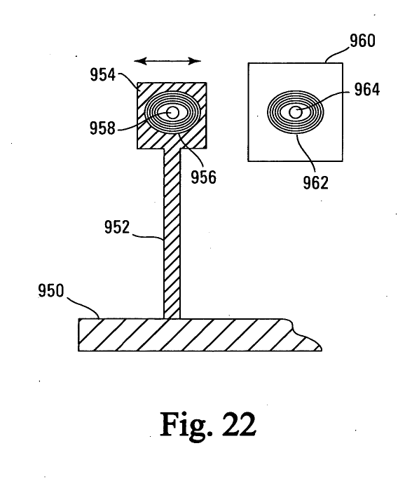

FIG. 22 illustrates a cross-sectional side view of a single cantilever, single axis embodiment including a substrate or base 950, a cantilever member 952 proximate to the substrate or base 950, a first magnetic field detector element 954, including a magnetic core 958 and a first inductor (e.g. a cylindrical coil) 956, proximate to the substrate or base 950 and adjoining the cantilever member 952, a first magnetic field emitter element 960, including a second magnetic core 964 and a second inductor (e.g. a cylindrical coil) 962, proximate to the substrate or base 950 and positioned within the detection range of the magnetic field detector element 954 such that deflection of the cantilever member 952 by a non-magnetic force results in a variation in output of the first magnetic field detector element 954.

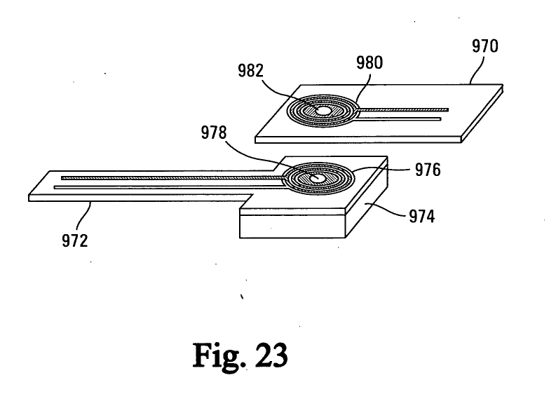

FIG. 23 illustrates a cross-sectional side view of a single cantilever, single axis embodiment including a substrate or base 970, a cantilever member 972 proximate to the substrate or base 970, a first magnetic field detector element 978 including a first pancake coil 976 proximate to the substrate or base 970 and adjoining the cantilever member 972, a first magnetic field emitter element 982 including a second pancake coil 980 proximate to the substrate or base 970 and positioned within the detection range of the first magnetic field detector element 978 such that deflection of the cantilever member 972 by a non-magnetic force results in a variation in output of the first magnetic field detector element 978. This embodiment illustrates an optional mass 974 proximate to the cantilever member 972.

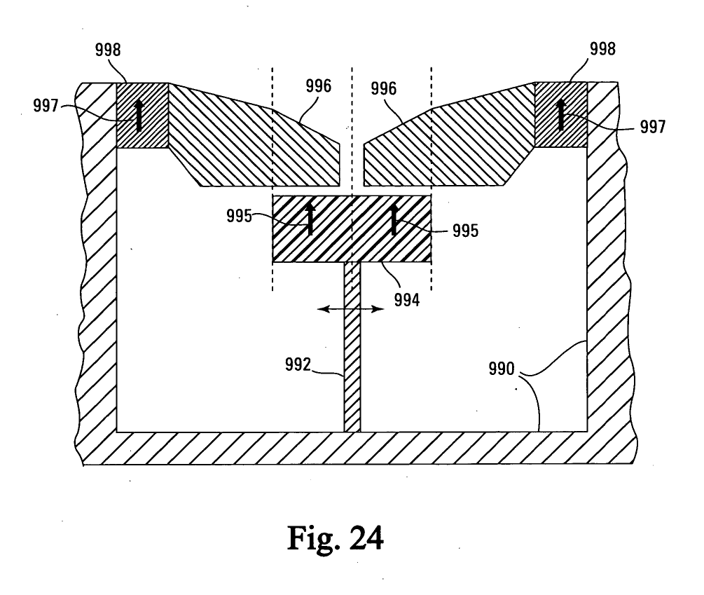

FIG. 24 illustrates a cross-sectional side view of a single cantilever, single axis embodiment including a substrate or base 990; a cantilever member 992 proximate to the substrate or base 990, a first magnetic field emitter element 994 comprising, for example, a permanent magnet having a magnetic field 995 oriented as shown, a first magnetic field detector element 998, including a magneto-resistive element comprising pair of flux guides 996 having a magnetic field 997 oriented as shown, proximate to the substrate or base 990 and positioned within the magnetic field 995 of the first magnetic field emitter 995 such that deflection of the cantilever member 992 by a non-magnetic force results in a variation in output of the first magnetic field detector element 998.

It will be understood by those skilled in the art that the use of a permanent magnetic material as an exemplary magnetic field element in the preceding and following examples is not intended to limit the scope of the invention to use of permanent magnet materials. The magnetic field elements used in the examples are exemplary, and the scope of this disclosure is intended to include all magnetic field elements and materials described herein and their equivalents.

Electrical Connections

In magnetic MEMS devices according to the present invention, one or more electrical connections provide a current or voltage to a magnetic field detector element and/or a first magnetic field emitter element. The electrical connections also communicate any change in voltage and current (also known as signal). The magnetic field emitter and/or detector elements can be connected to one or more optional electronic circuit elements using one or more conductive leads preferably made from electrically conductive material such as gold or copper.

For example, as shown in FIG. 13, conductive leads 506, 514, and 524 provide a path for signal communication to and from magnetic field emitter elements 504, 512, and 522 (not shown) and magnetic field detector elements 506, 514, and 524 (the leads are respectively labeled 507, 517, and 525). In this manner, a magnetic MEMS device having only a single pair of conductive leads may provide electrical signal communication and/or electrical power to a plurality of magnetic field elements on a single substrate or base.

Optional Electronic Circuit Elements

At least one electronic circuit can optionally be disposed on or within the substrate or base, such as a circuit for driving, detecting, controlling, and processing electronic signals. In some embodiments, the electronic circuit is formed on a surface of or within the substrate or base. The electronic circuit preferably is communicably proximate to one or more magnetic field elements proximate to the substrate or base. More preferably, the electronic circuit is proximate to at least one magnetic field emitter element and one magnetic field detector element proximate to the substrate or base.

In a preferred embodiment, at least one electronic interface circuit is providing on or within the substrate or base for processing data. The electronic circuit preferably includes at least one electronic circuit element selected from a conductive lead, power source, a pre-amplifier, a modulator, a demodulator, a filter, an analog to digital computer, a digital to analog converter, and a digital signal processor. A transceiver and integrated on-chip antenna can also be integrated on or within the substrate or base for applications requiring communications between a plurality of magnetic field elements according to the present invention or between a magnetic MEMS device according to the present invention and a remotely located system for digital signal processing.

Optional Mass

As noted herein, magnetic field elements according to the present invention may be used to determine the magnitude of an external non-magnetic force applied to the magnetic field element. Thus, the magnitude of the deflection or movement of the member resulting from an external non-magnetic force may be determined by detecting a variation in magnetic field at a magnetic field element. The mass of the member, the mechanical properties of the member (i.e. spring constant), and the magnitude of deflection or movement of the member all may be used to calculate the magnitude of the external non-magnetic force applied to the member. The mass of the member may be varied to provide different force detection ranges for the magnetic field element.

Exemplary Magnetic MEMS Device Fabrication Embodiments

In general, magnetic MEMS devices according to the present invention include a substrate or base, a member extending from the substrate or base, and two or more magnetic field elements, these elements including at least one magnetic field emitter element having a magnetic field and positioned proximate to the substrate or base, and at least one magnetic field detector element positioned within the magnetic field of the magnetic field emitter element such that deflection of the member by a non-magnetic force results in a variation in output of magnetic field detector element. Preferably, one of the magnetic field elements, either the emitter or the detector, is positioned on a surface of the member, and the second magnetic field element, either the corresponding detector or emitter, is positioned proximate to the substrate or base and preferably on the substrate within a cavity extending under at least a portion of the member, such that the member covers at least a portion of the cavity.

Exemplary Magnetic MEMS Device Fabrication Materials

Various materials can be used to define the various structural elements of magnetic MEMS device according to the present invention, including, but not limited to, substrate or bases, structural materials, functional materials, sacrificial materials, release materials and the like.

Some preferred embodiments according to the present invention make use of optional structural, functional, sacrificial layers or release layers. Generally, structural layers include materials that remain part of the final structure after completion of the fabrication process. Functional layers are generally structural layers that perform a function in the assembled structure, for example, a permanent magnet useful as magnetic field emitters. Generally, all or part of a sacrificial layer, if present, is removed during fabrication. In some preferred embodiments, the same material is used both as a structural and as a sacrificial layer. A release layer is generally a material that provides a surface release function for other layers deposited on top of the release layer during fabrication of the magnetic MEMS device, thereby permitting separation of those layers from the device substrate or base.

Substrate or Bases

The substrate or bases according to the present invention can preferably include, but are not limited to, low-parasitic insulating substrate or bases (including but not limited to silicon nitride, silicon carbide, silicon dioxide, and metal oxides such as alumina), glass substrate or bases (including but not limited to pyrex wafers, fused quartz wafers or single crystalline quartz wafers); sapphire substrate or bases, silicon substrate or bases, or other semiconductor substrate or bases. The substrate or baseaccording to the present invention may also include single crystal silicon wafers, epitaxial growth silicon wafers, silicon-on-insulator (SOI) wafers, silicon-on-glass (SOG) wafers, and the like.

Structural Materials

Structural materials are generally used to fabricate or support the member, for example, cantilever, beam or membrane structures. Structural layers according to some embodiments of the present invention can be one or more layers of various materials including, but not limited to, polysilicon, silicon carbide, silicon nitride, single crystalline silicon, silicon-germanium, other semiconductors, metals or metal alloys, alumina and other metal oxides, silicon oxide, silicon oxynitrite and other ceramics, polymers or any combination of these materials. The preferable materials are polysilicon, single crystalline silicon, or nickel copper.

Functional Materials

Functional materials are generally used to provide a specific performance aspect useful in fabricating or operating a magnetic field element, although in some cases functional materials may serve a dual role as a functional/structural material. Functional materials include ferromagnetic or paramagnetic materials useful in fabricating magnetic field elements. Functional layers useful in fabricating magnetic field elements according to some embodiments of the present invention can be one or more layers of various materials including but not limited to ferromagnetic metals (e.g. iron, nickel, cobalt, samarium, neodymium and the like), metal alloys (e.g. alloys of nickel, cobalt, iron, samarium, or neodymium, or additionally with other metals such as chromium or platinum), and paramagnetic materials (e.g. iron oxides, cobalt oxides, and the like).

Sacrificial Materials

Sacrificial materials are generally used to provide a transient masking or protective function in the magnetic MEMS device fabrication process, although in some cases, sacrificial materials may become part of the magnetic MEMS device and thus serve as dual structural/sacrificial material. Optional sacrificial layers useful in fabricating magnetic MEMS devices according to some embodiments of the present invention can be layers of various materials, including but not limited to, silicon oxide, undoped silicon oxide, germanium, copper, aluminum, other metals and metal alloys, polyimide, (co)polymers, graphite, or any combination of these materials.

Release Materials

Release materials are a type of sacrificial material generally used to provide a transient masking or protective function, or a temporary base on which to build structural or functional layers in the magnetic MEMS device fabrication process. An example of a release layer is a bi-layered photoresist to create an undercut useful in allowing chemicals to more readily reach the photoresist and augment the lift-off process. Optional release layers useful in fabricating magnetic MEMS device according to some embodiments of the present invention can be layers of various materials, including but not limited to photopolymers (e.g. commercially available photoresists), copper, aluminum, other selectively-removable metals, silicon, polymers, graphite, or any combination of these materials.

Exemplary Fabrication Processes

Various microfabrication processes can be used to fabricate the magnetic MEMS device according to some embodiments of the present invention, and include, but are not limited to, material patterning processes, material depositing processes, material removal processes, material bonding processes, and the like. These processes are repeated according to an ordered sequence to produce the layers and features necessary for the desired magnetic MEMS device.

Material Patterning Processes

Exemplary material patterning processes include, but are not limited to, lithographic, micro-lithographic and interference-lithographic exposure processes, electroplating, electroless plating, ion mill, electrochemical mill (plasma etch) or electromagnetic radiation (laser), and the like. Photolithography is a preferred method for patterning the various layers. Lithography in the MEMS context is generally the transfer of a pattern to a photosensitive material by selective exposure to a source of actinic radiation such as light (e.g. ultraviolet, visible or infrared light) or an electron beam. When a photosensitive material is selectively exposed to actinic radiation, for example by masking some of the radiation (e.g. with a lithographic mask bearing a pattern corresponding to a lithographic master), the lithographic master pattern may be transferred to the photosensitive material according to the exposure through the mask. In this manner, the properties of the exposed and unexposed regions differ.

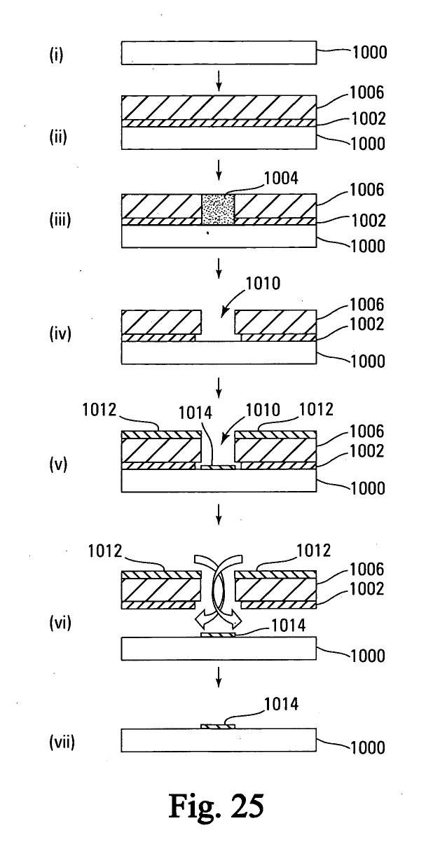

FIG. 25 is a cross-sectional view block diagram illustrating an exemplary sequence of steps useful in practicing a photolithographic patterning, chemical vapor material deposition process to prepare exemplary magnetic MEMS structures on a substrate or base according to certain embodiments of the present invention. The exemplary steps include:
(i) providing a substrate or base 1000;
(ii) depositing (e.g. by spin-coating) a photoresist 1002 and 1006 to the substrate or base 1000;
(iii) exposing the photoresist 1002 and 1006 with actinic (e.g. ultraviolet) radiation to process the pattern of the desired structure 1004 into the photoresist 1002 and 1006 on the substrate or base 1000;
(iv) removing (e.g. by etching through the photoresist 1006 and 1002) in either the exposed (positive resist) or non-exposed (negative resist) portion of the photoresist 1002 (thereby creating an undercut) and 1006 to create a pattern 1010 corresponding to the desired structure on the substrate or base 1000;
(v) depositing (e.g. by vapor deposition) the structural or functional material 1012 on the photoresist 1006 and the substrate or base 1000 to define a pattern 1010 corresponding to the desired structure on the substrate or base 1000;
(vi) removing photoresist 1002 and 1006, and structural or functional layer 1012, for example, by chemical etch, leaving behind the structural or functional material corresponding to the desired structure 1014 on substrate or base 1000;
(vii) yielding the completed structure 1014 positioned on a surface of the substrate or base 1000.
   Material Deposition Processes

Material deposition processes may be used to deposit thin films of material on a substrate, and include deposition from chemical reactions and deposition from physical reaction. Deposition from chemical reactions includes chemical vapor deposition, electrodeposition, molecular beam epitaxy, and thermal oxidation. These chemical reaction deposition processes generally deposit solid material created from a chemical reaction in a gas or liquid composition or between a gas or liquid composition and the substrate material. Generally, the chemical reaction will also produce one or more byproducts, which may be in the form of a gas, liquid, or solid. Deposition from physical reactions includes mass transfer vapor deposition (e.g., evaporation or sputtering) and casting. Generally, depositions from physical reactions deposit material directly on the substrate by mass transfer without creating a chemical byproduct.

Suitable material deposition processes include, but are not limited to, sputtering, evaporation, casting, electroplating, electroless plating, chemical vapor, ionic plasma, spin coating, laser assisted processes, and the like.

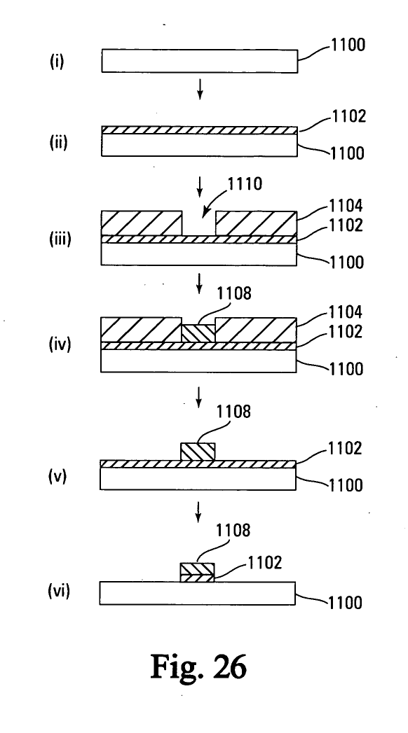

FIG. 26 is a cross-sectional view block diagram illustrating an exemplary sequence of steps useful in practicing an electroplating material deposition process to prepare exemplary magnetic MEMS structures on a substrate or base according to certain embodiments of the present invention. The exemplary steps include:
(i) providing a substrate or base 1100;
(ii) depositing (e.g. by sputter deposition) a thin metal seedlayer 1102 on a surface of the substrate or base 1100
(iii) depositing (e.g. by spin coating) a photoresist 1104, exposing and developing photoresist 1104 to create a pattern 1110, corresponding to the desired structure on the substrate or base 1100;
(iv) depositing (e.g. by electroplating) a structural or functional material on the seedlayer 1102 in the area of the pattern 1110, to create the desired structure 1108 on the seedlayer 1102 over the substrate or base 1100;
(v) removing (e.g. by chemical etching) the photomask 1104 while retaining the desired structure 1108 on the seedlayer 1102 over the substrate or base 1100;
(vi) removing (e.g. by ion milling) at least a portion and preferably all of the seedlayer 1102 while retaining the desired structure 1108 on the remaining portion of the seedlayer 1102 over the substrate or base 1100. Note that the desired structure 1108 may become thinner during this seedlayer material removal process.
   Material Removal Processes

Exemplary material removal processes include, but are not limited to, surface micro-machining, bulk micromachining, plasma etching, reactive ion etching (RIE), deep reactive ion etching (DRIE), bond-etchback etching, chemical etching, wet etching, selective wet chemical etching, ion milling, chemical mechanical polishing, lapping, grinding, burnishing, and the like.

Surface micromachining is a process involving the selective removal of one or more material layers built up on a substrate. The bulk of the substrate remains untouched. In contrast, in bulk micromachining, large portions of the substrate are removed to form the desired structure. Structures with greater heights may be formed by bulk micromachining because thicker substrates can be used relative to surface micromachining. Etching is a process for removing portions of a deposited film or the substrate itself. Two general types of etching processes include wet etching and dry etching. Wet etching selectively removes material by dissolving the material upon contact with a liquid chemical etchant. Dry etching selectively removes material using a directed plasma beam, a directed reactive ion beam, a vapor phase etchant, and the like.

One particular material removal process, known as wafer planarizing, is particularly useful for obtaining a flat or planar surface on which to build magnetic MEMS structures. In some preferred embodiments, wafer planarizing is carried out by polishing, chemical mechanical polishing, lapping, grinding, burnishing, and the like. In particular, burnishing may be used to correct for small defects in the planarity of the substrate surface or a layer deposited on a surface of the substrate.

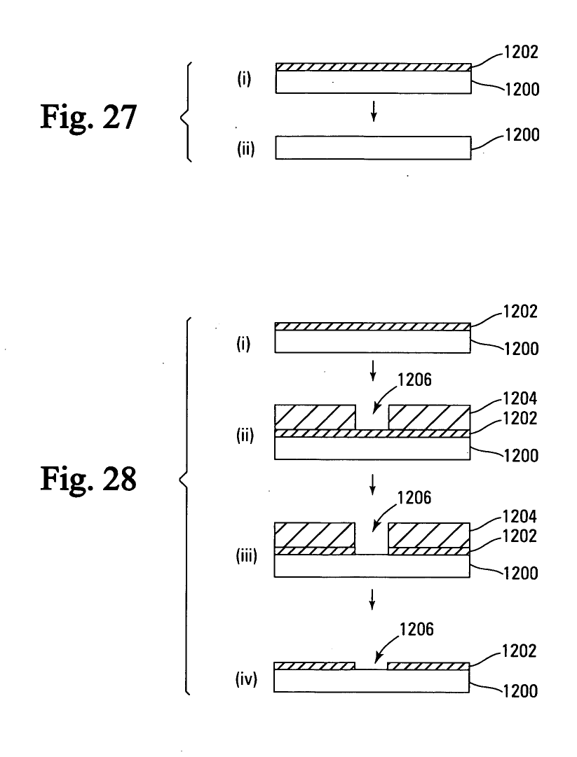

FIG. 27 is a cross-sectional view block diagram illustrating an exemplary sequence of steps useful in practicing a selective material removal process useful in preparing exemplary magnetic MEMS structures on a substrate or base according to certain embodiments of the present invention. The exemplary steps include:
(i) providing a substrate or base 1200 having a film 1202;
(ii) removing (e.g. by wet chemical etching or ion mill dry etching) the film 1202 from the substrate or base 1200.

FIG. 28 is a cross-sectional view block diagram illustrating another exemplary sequence of steps useful in practicing a selective material removal process useful in preparing exemplary magnetic MEMS structures on a substrate or base according to certain embodiments of the present invention. The exemplary steps include:
(i) providing a substrate or base 1200, bearing a film 1202;
(ii) depositing a functional mask material (e.g. a photoresist) 1204 by exposing and developing photoresist 1204 to create pattern 1206, corresponding to the desired structure on the substrate or base 1200;
(iii) removing (e.g. by wet chemical etching or ion mill dry etching) a portion of the film 1202 from the substrate or base 1200, where exposed through the pattern 1206 of the mask 1204;
(iv) removing (e.g. by wet chemical etching) the mask 1204, leaving a portion of the film 1202 while retaining the desired structure 1202 on the surface of the substrate or base 1200.

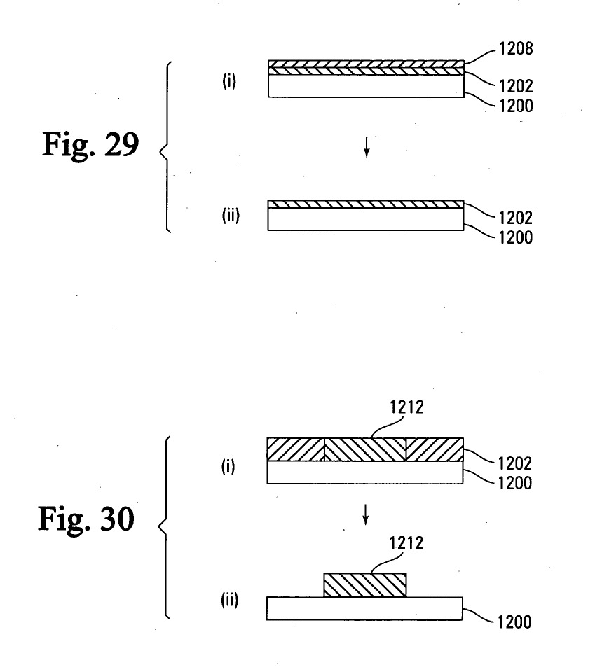

FIG. 29 is a cross-sectional view block diagram illustrating an exemplary sequence of steps useful in practicing an alternative selective material removal process useful in preparing exemplary magnetic MEMS structures on a substrate or base according to certain embodiments of the present invention. The exemplary steps include:
(i) providing a substrate or base 1200 including a first functional material (e.g. an etch stop) 1202 and a second functional material (e.g. a photoresist) 1208 arranged in layers as shown in FIG. 29(i);
(ii) removing (e.g. by selective wet chemical etching) the second functional material 1208 leaving the first functional material 1202 on the surface of the substrate or base 1200.

FIG. 30 is a cross-sectional view block diagram illustrating another exemplary sequence of steps useful in practicing a selective material removal process useful in preparing exemplary magnetic MEMS structures on a substrate or base according to certain embodiments of the present invention. The exemplary steps include:
(i) providing a planarized substrate or base 1200 bearing a first sacrificial material (e.g. a metal such as copper) 1202 and a first functional material (e.g. a metal such as nickel) 1212 arranged to form a single layer as shown in FIG. 30(i);
(ii) removing (e.g. by selective wet chemical etching) the first sacrificial material 1202, leaving the first functional material 1212 on the surface of the substrate or base 1200.
   Combined Fabrication Processes

Exemplary material patterning, material depositing ion and material removal processes may be combined to fabricate magnetic MEMS devices, transducers, electronic devices, sensors and accelerometers according to some embodiments of the present invention. For example, lithography, plating and molding (e.g. LIGA) processes, combining lithographic with electroplating and molding processes, are preferred processes to obtain depth of MEMS elements or features. In LIGA, patterns are typically created in a substrate using lithography and then electroplated to create three-dimensional molds. These molds can be used as the final product, or various materials can be injected or coated into them. LIGA processes allow materials (e.g. metals, ceramics, plastics, and the like) other than the wafer materials (e.g. silicon, polysilicon, doped silicon, and the like) to be used in fabricating the MEMS device. In addition, LIGA processes allow for fabrication of devices with very high aspect ratios or feature depths.

Deposition, etching and lithography processes may occur in combination repeatedly in order to produce a single MEMS structure. Lithography may be used to mask portions of a film or the substrate. Masked portions may be protected during a subsequent etching process to produce precise MEMS structures. Conversely, masked portions may themselves be etched. This process can be used to make a component or a mold for a component. For example, multiple layers of film can be deposited onto a substrate. Following each deposition step, a lithography step may be preformed to define a desired cross section of a MEMS structure through that layer. After a desired number of layers have been deposited and individually subjected to radiation patterns in lithography steps, portions of the layers defining the MEMS structure can be removed with a single etching process, leaving a mold behind for the desired MEMS structure. A compatible material may then be injected into the mold to produce the desired MEMS structure. Precise and complex device structures thus may be produced using a combination of MEMS and semi-conductor fabrication techniques.

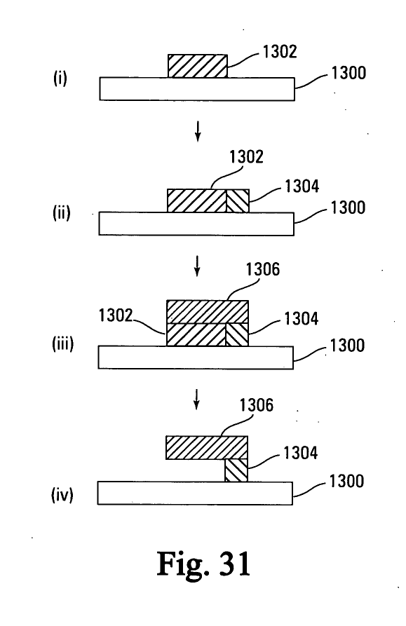

FIG. 31 is a side view diagram illustrating an exemplary sequence of steps useful in practicing a sequential material depositing ion/selective material removal process useful in preparing exemplary magnetic MEMS structures on a substrate or base according to certain embodiments of the present invention. The exemplary steps include:
(i) providing a substrate or base 1300, having a deposited (e.g. by electroplating deposition) sacrificial or release material in a first pattern 1302 as shown in FIG. 31(i);
(ii) depositing (e.g. by electroplating) a structural or functional material in a second pattern 1304 on the surface of the substrate or base 1300 adjacent to the sacrificial or release material defining the first pattern 1302 as shown in FIG. 31(ii)
(iii) depositing (e.g. by electroplating) a structural or functional material in a third pattern 1306 on the surface of the materials defining the first pattern 1302 and the second pattern 1304 on the substrate or base 1300, as shown in FIG. 31(iii)
(iv) selectively removing (e.g. by selective wet chemical etching as described above) the sacrificial or release material defining the first pattern 1302, leaving behind the desired structural feature formed by the structural or functional materials depositing as the second pattern 1304 and the third pattern 1306 on the substrate or base 1300 as shown in FIG. 31(iv)
   Material Bonding Processes

Material bonding processes for providing electrical connections and/or mechanical attachment can be used in some embodiments of the current invention. Exemplary material bonding processes include, but are not limited to, thermal compression bonding, cold welding, solder bump bonding, gold thermal compression bonding, gold-indium or indium bump bonding, gold-tin eutectic bonding, polymer bump bonding, adhesive bonding, bonding involving the formation of one or more amalgams, or any combination of these processes and the like.

In some embodiments, the material bonding process creates a hermetic seal suitable for containing fluids within the MEMS device. The contained fluid may be a gas or liquid. For example, the fluid may be air, nitrogen, helium, or another gas. Alternatively, the fluid may be a liquid fluid such as a silicone oil, a perfluorinated solvent, or other similar liquids. In some embodiments, the fluid may be selected to be a chemically inert, low-conductivity liquid having a viscosity suitable for providing viscous dampening of the deflectable member.

In certain embodiments wherein there are fragile bonds, a soft under-fill may be used to protect these bonds. The under-fill material may be applied to the whole underside of the chip, or selectively, e.g. to the corners or under the center. Other additional techniques for providing mechanical stability can also be used, including but not limited to thermal compression bonding, cold welding, solder bonding, polymer bump bonding, solder bump bonding, eutectic bonding, adhesive bonding, bonding involving the formation of one or more amalgams, or any combinations of these processes and the like.

In certain preferred embodiments, a protective layer is providing over the surface of the substrate or base to cover and protect various components of the magnetic MEMS device from contamination and damage. The present invention can be packaged and sealed using packaging materials and methods, including but not limited to using ceramic or metal hermetic packages. In certain preferred embodiments, one or more of the protective layer, the packaging or sealing materials provide a magnetic field shielding function, protecting the present invention from the influence of external magnetic fields.

Sealing is preferably achieved by bonding to the surface of the substrate or base at least one seal material using a seal bonding material. Exemplary seal materials include, but are not limited to, silicon nitride, silicon carbide, silicon dioxide, and metal oxides such as alumina); glass substrate or bases (including but not limited to pyrex wafers, fused quartz wafers or single crystalline quartz wafers); sapphire substrate or bases, silicon substrate or bases, other semiconductor substrate or bases, ceramics, polymers and the like. Preferred seal materials include, but are not limited to, single crystal silicon wafers, epitaxial growth silicon wafers, silicon-on-insulator wafers, silicon-on-glass wafers, and the like.

Exemplary seal bonding materials include, but are not limited to, metals, metal alloys, solders, polymers, adhesives, any combination of these materials, and the like. In some exemplary embodiments, a suitable seal bonding material is electroplated gold. In other exemplary embodiments involving the joining of two substrate or bases to produce an integrated magnetic MEMS device, the seal material can be fabricated using the same device layers as the bumps for interconnecting the substrate or bases, and a bump bonding process can be used to seal a protective layer over the surface of the substrate or base to cover and protect the various components of the magnetic MEMS device from contamination and damage.

In some embodiments where two or more substrate or bases are bonded together and the gap between the substrate or bases is important, spacers can be used to control the gap during and/or after the bonding process. Preferably in these cases, the spacers are fabricated using any, some, or all of the existing device or packaging layers, without adding additional layers.

Fabrication of Exemplary Magnetic MEMS devices

Various processes for fabricating magnetic MEMS devices, transducers, electronic devices, sensors and accelerometers according to the present invention will now be described, by way of example, with reference to the accompanying drawings. One skilled in the art will understand that certain features, shapes and positions of elements depicted in the figures can be altered or varied without conflicting with or deviating from the scope of the presently disclosed invention.

Exemplary Single Cantilever Fabrication Processes

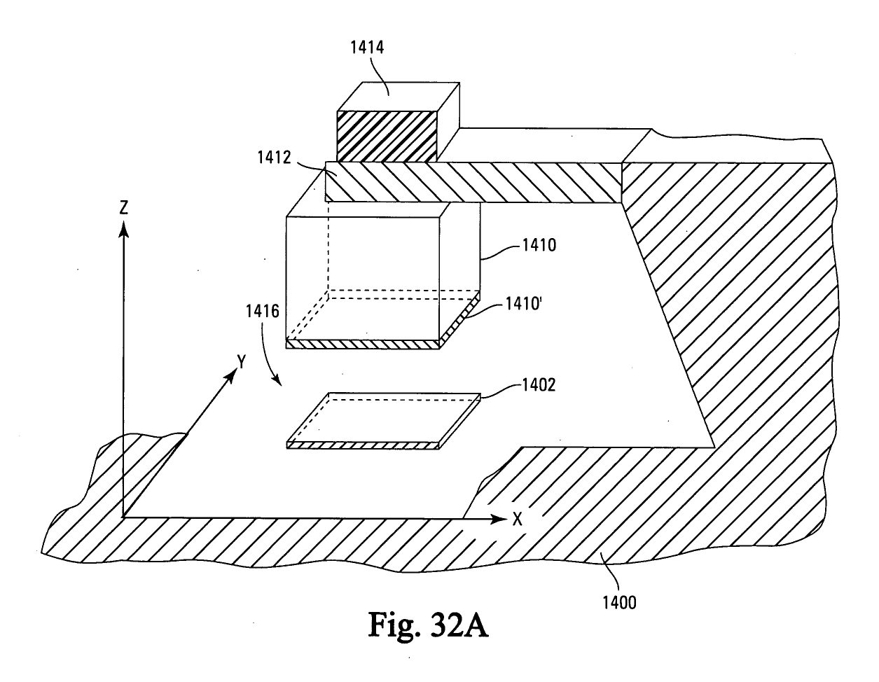

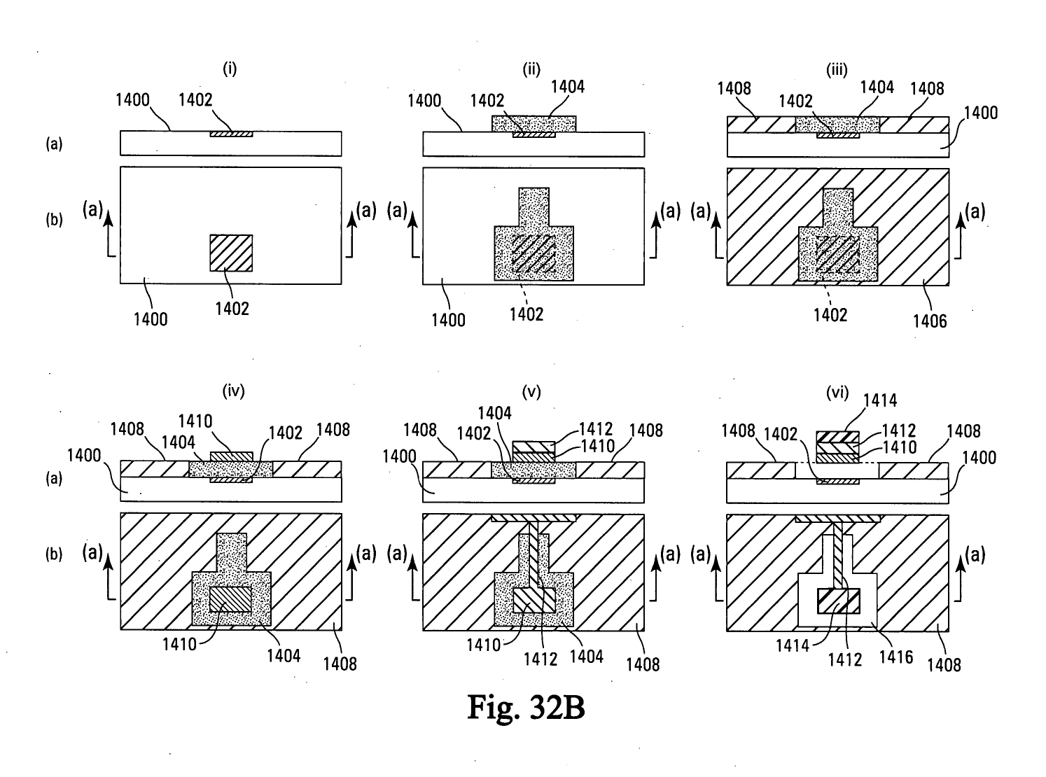

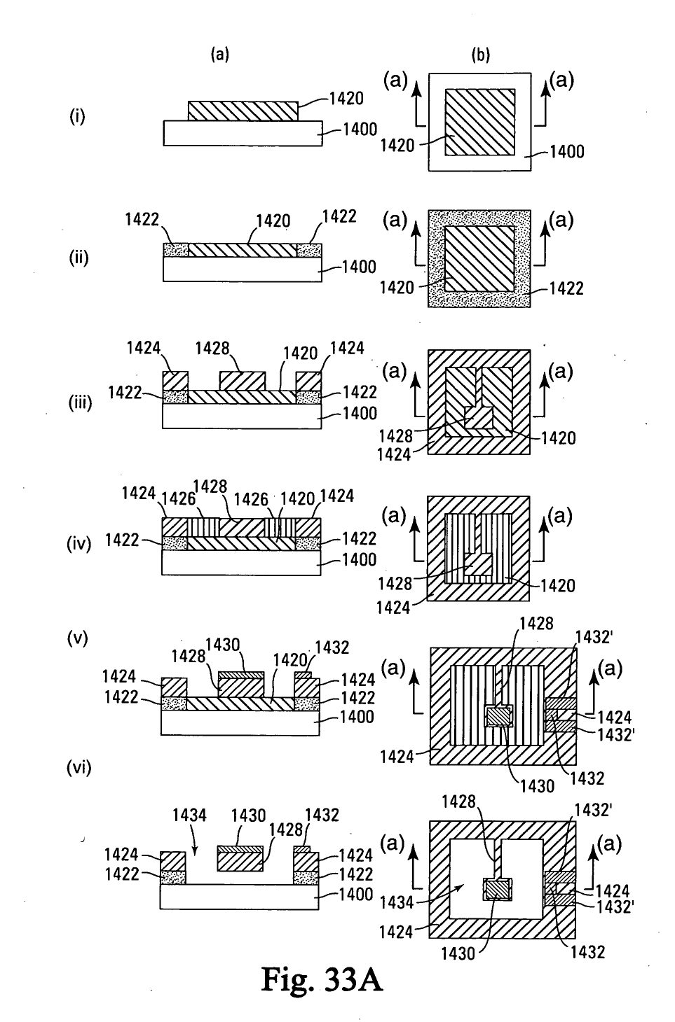

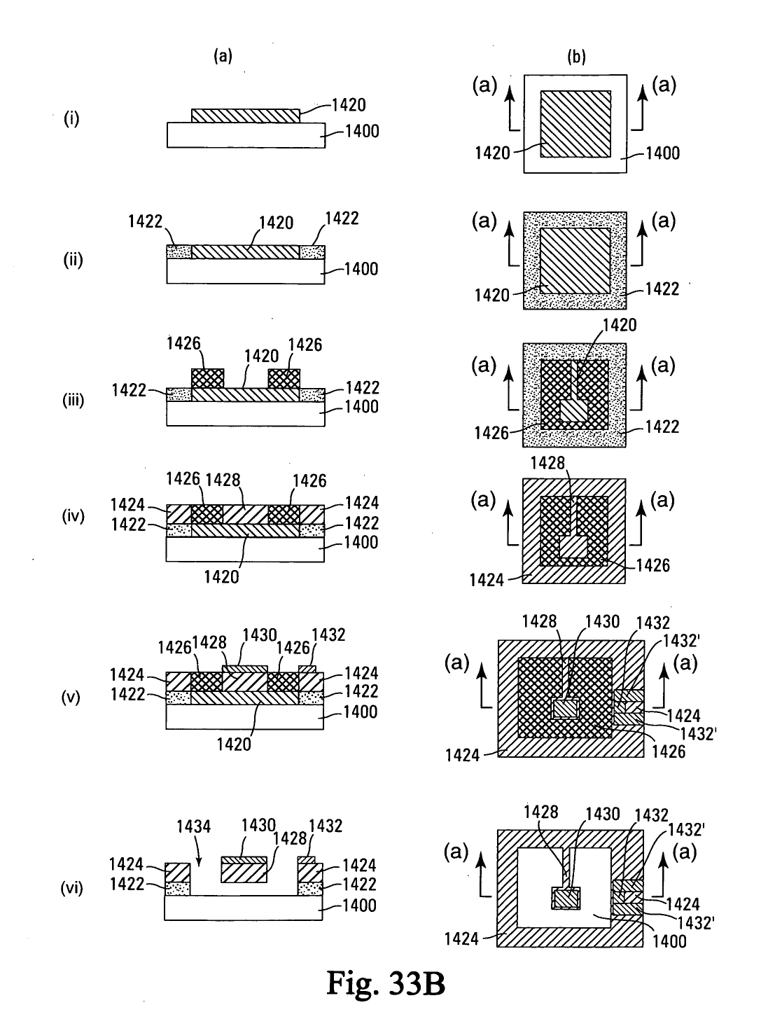

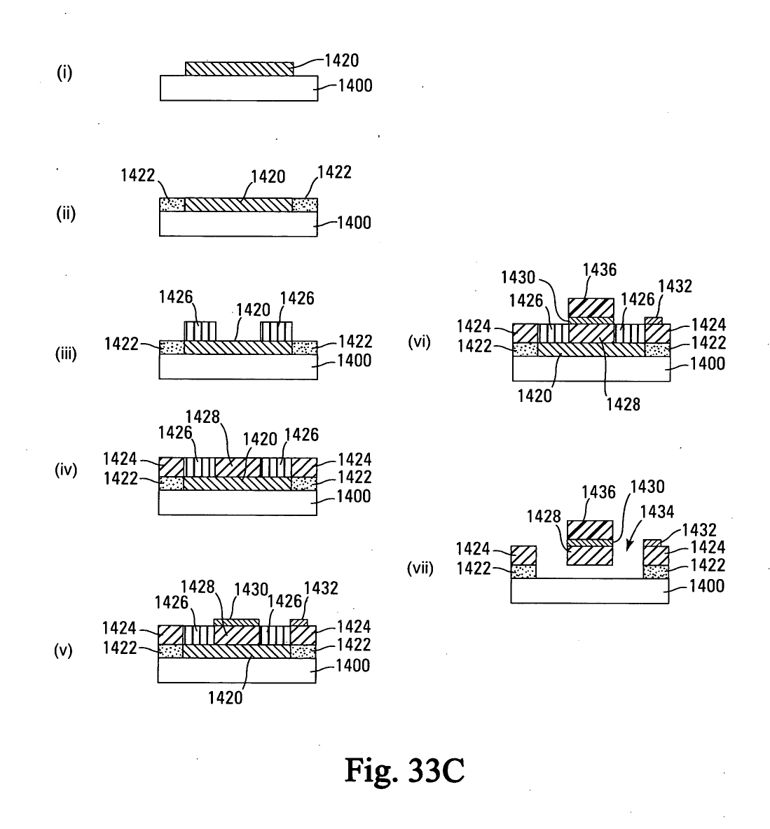

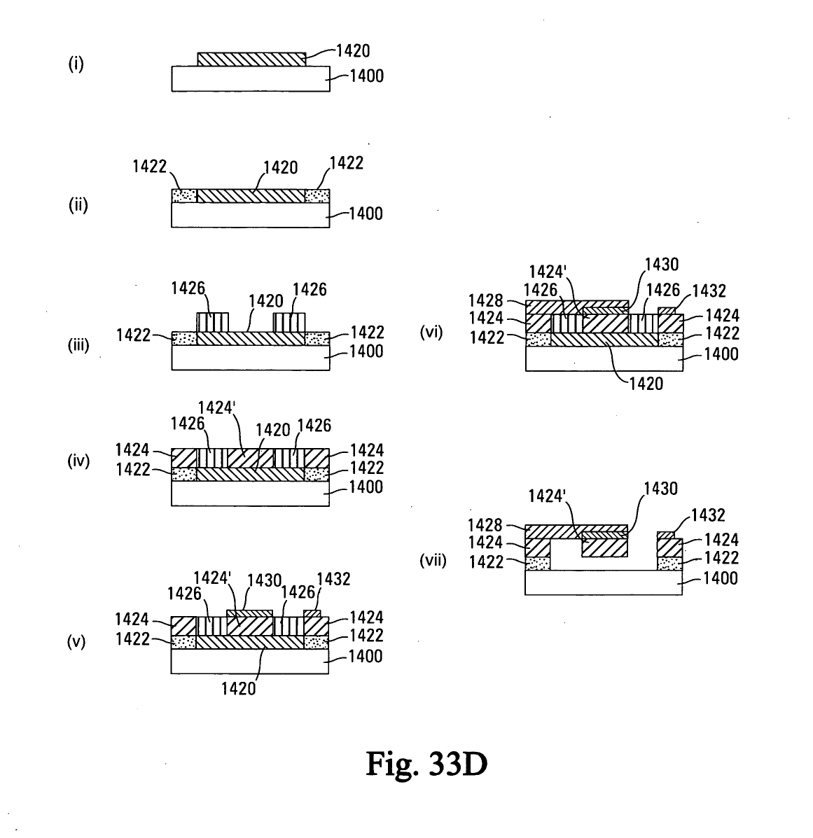

FIGS. 32-33 illustrate exemplary processes useful in preparing a magnetic MEMS device having a cantilever member according to one embodiment of the present invention.

FIG. 32A provides a perspective view of a single cantilever, single axis embodiment including a substrate or base 1400, a cantilever member 1412 proximate to the substrate or base, a first magnetic field emitter element 1410′ on the surface of an optional mass 1410 proximate to the substrate or base and adjoining the cantilever member 1412, a first magnetic field detector element 1402 proximate to the substrate or base and positioned within a cavity 1416 defined by the substrate or base and within the magnetic field of the magnetic field emitter element 1410′ such that deflection of the cantilever member 1412 by a non-magnetic force results in a variation in output of the first magnetic field detector element 1402.

FIGS. 32B(a) and 32B(b), cross-sectional and top views, respectively, represent one exemplary processing sequence useful in fabricating a magnetic MEMS device having a cantilever member according to one embodiment of the present invention illustrated in FIG. 32A, the processing sequence including the steps of:
(i) providing a substrate or base 1400, having a first magnetic field emitter element 1402;
(ii) depositing (e.g. by electroplating) a release material layer 1404 over the first magnetic field detector element 1402 on the substrate or base 1400;
(iii) depositing (e.g. by electroplating or sputter deposition) a structural material layer 1408 adjacent to the release material layer 1404 over the first magnetic field emitter element 1402, thereby covering the exposed portions of the substrate or base 1400, and planarizing (e.g. by chemical mechanical polishing) the deposited layers.
(iv) depositing (e.g. by electroplating or sputter deposition) a functional material (e.g. a PM material) to form a first magnetic field emitter element 1410 on the surface of the release material layer 1404;
(v) depositing (e.g. by electroplating or sputtering depositing) a structural material layer to form a cantilever member 1412 above the first magnetic field emitter element 1410 on the surface of the release material layer 1404;
(vi) depositing (e.g. by electroplating) an optional mass 1414 on the cantilever member 1412 above the first magnetic field emitter element 1410 on the surface of the release material layer 1404, and removing the release material layer 1404 to create a cavity 1416, thereby freeing the cantilever member 1412 from the substrate or base 1400 at an end distal from the substrate or base.

FIGS. 33A(a) and 33A(b), cross-sectional and top views, respectively, represent one exemplary processing sequence useful in fabricating a magnetic MEMS device having a cantilever member according to another embodiment of the present invention, the processing sequence including the steps of:
(i) depositing (e.g. by electroplating) a first release material layer 1420, on a surface of a substrate or base 1400;
(ii) depositing (e.g. by electroplating or sputter deposition) a structural material layer 1422, adjacent to the release material layer 1420, thereby covering the exposed portions of the substrate or base 1400, and planarizing (e.g. by chemical mechanical polishing) the deposited layers;
(iii) depositing (e.g. by electroplating) a structural material layer on the exposed surface of the deposited layers to form a cantilever member 1428 proximate to a frame 1424 as shown in FIG. 33A(iii);
(iv) depositing (e.g. by electroplating or sputter deposition) a second release material layer 1426, on the exposed surface of the first release material layer 1420 between the cantilever member 1428 and the frame 1424, and planarizing (e.g. by chemical mechanical polishing) the deposited layers as shown in FIG. 33A(iv);
(v) depositing (e.g. by electroplating or sputter deposition) a functional material (e.g. a PM material) to form a first magnetic field emitter element 1430 on an exposed surface of the cantilever member 1428, and depositing (e.g. by electroplating or sputter deposition) a functional material to form a first magnetic field detector element 1432 and conductive leads 1432′, wherein the magnetic field detector element 1432 is positioned within the magnetic field of the magnetic field emitter element 1430 on an exposed surface of the frame 1424 as shown in FIG. 33A(v), and removing (e.g. by selective wet chemical etching) the second release material layer 1426.
(vi) removing (e.g. by selective wet chemical etching) the first release material layer 1420 to create a cavity 1434, thereby freeing the cantilever member 1428.

FIGS. 33B(a) and 33B(b), cross-sectional and top views, respectively, represent another exemplary processing sequence useful in fabricating a magnetic MEMS device having a cantilever member according to another embodiment of the present invention, the processing sequence including the steps of:
(i) depositing (e.g. by electroplating or sputter deposition) a first release material layer 1420, on a surface of a substrate or base 1400;
(ii) depositing (e.g. by electroplating or sputter deposition) a first structural material layer 1422, adjacent to the release material layer 1420, thereby covering the exposed portions of the substrate or base 1400, and planarizing (e.g. by chemical mechanical polishing) the deposited layers;
(iii) depositing (e.g. by electroplating) a second release material layer 1426 on the exposed surface of the deposited layers to form a mask corresponding to a pattern for a cantilever member proximate to a frame as shown in FIG. 33B(iii);
(iv) depositing (e.g. by electroplating or sputter deposition) a second structural material layer on the exposed surface of the first release material layer 1420 and the first structural material layer 1422 through the mask created by the second release layer 1426 to fabricate a cantilever member 1428 proximate to a frame 1424, and planarizing (e.g. by chemical mechanical polishing) the deposited layers as shown in FIG. 33B(iv);
(v) depositing (e.g. by electroplating or sputter deposition) a functional material (e.g. a PM material) to form a first magnetic field emitter element 1430 on an exposed surface of the cantilever member 1428, and depositing (e.g. by electroplating or sputter deposition) a functional material to form a first magnetic field detector element 1432 and conductive leads 1432′, wherein the magnetic field emitter element 1432 is positioned within the magnetic field of the magnetic field emitter element 1430 on an exposed surface of the frame 1424 as shown in FIG. 33B(v);
(vi) removing (e.g. by selective wet chemical etching) the second release material layer 1426, and the first release material layer 1420 to expose the substrate or base 1400, thereby freeing the cantilever member 1428.

FIG. 33C, cross-sectional view only, represents another exemplary processing sequence useful in fabricating a magnetic MEMS device having a cantilever member according to another embodiment of the present invention, the processing sequence including the steps of:
(i) depositing (e.g. by electroplating) a first release material layer 1420, on a surface of a substrate or base 1400;
(ii) depositing (e.g. by electroplating or sputter deposition) a first structural material layer 1422, adjacent to the release material layer 1420, thereby covering the exposed portions of the substrate or base 1400, and planarizing (e.g. by chemical mechanical polishing) the deposited layers as shown in FIG. 33C(ii);
(iii) depositing (e.g. by electroplating) a second release material layer 1426 on the exposed surface of the deposited layers to form a mask corresponding to a reverse pattern for a cantilever member as shown in FIG. 33C(iii);
(iv) depositing (e.g. by electroplating or sputter deposition) a second structural material layer on the exposed surface of the first release material layer 1420 and the first structural material layer 1422 through the mask created by the second release layer 1426, to fabricate a cantilever member 1428 proximate to a frame 1424, and planarizing (e.g. by chemical mechanical polishing) the deposited layers as shown in FIG. 33C(iv);
(v) depositing (e.g. by electroplating or sputter deposition) a functional material (e.g. a PM material) to form a first magnetic field emitter element 1430 on an exposed surface of the cantilever member 1428, and depositing a functional material to form a first magnetic field detector element 1432 positioned within the magnetic field of the magnetic field emitter element 1430 on an exposed surface of the frame 1424 as shown in FIG. 33C(v);
(vi) depositing (e.g. by electroplating or sputter deposition) a structural material layer to form a first optional mass 1436.;
(vii) removing (e.g. by selective wet chemical etching) the first release material layer 1420 and second release material layer 1426 sufficient to create a cavity 1434, thereby freeing the cantilever member 1428;

FIG. 33D, cross-sectional view only, represents another exemplary processing sequence useful in fabricating a magnetic MEMS device having a cantilever member according to another embodiment of the present invention, the processing sequence including the steps of:
(i) depositing (e.g. by electroplating) a first release material layer 1420, on a surface of a substrate or base 1400;
(ii) depositing (e.g. by electroplating or sputter deposition) a first structural material layer 1422, adjacent to the release material layer 1420, thereby covering the exposed portions of the substrate or base 1400, and planarizing (e.g. by chemical mechanical polishing) the deposited layers as shown in FIG. 33D(ii);
(iii) depositing (e.g. by electroplating) a second release material layer 1426 on the exposed surface of the deposited layers to form a mask corresponding to a pattern for a cavity as shown in FIG. 33D(iii);
(iv) depositing (e.g. by electroplating or sputter deposition) a sacrificial structural material layer on the exposed surface of the first release material layer 1420 and the first structural material layer 1422, to define frame 1424 and optional proof mass 1424′, and planarizing (e.g. by chemical mechanical polishing) the deposited layers as shown in FIG. 33D(iv);
(v) depositing (e.g. by electroplating or sputter deposition) a functional material (e.g. a PM material) to form a first magnetic field emitter element 1430 on an exposed surface of the optional mass 1424′, and depositing (e.g. by electroplating or sputter deposition) a functional material to form a first magnetic field detector element 1432 positioned within the magnetic field of the magnetic field emitter element 1430 on an exposed surface of the frame 1424 as shown in FIG. 33D(v);
(vi) depositing (e.g. by electroplating or sputter deposition) a second structural material layer 1428 to define cantilever member 1428;
(vii) removing (e.g. by selective wet chemical etching) first release layer 1420 and second release layer 1426 as shown in FIG. 33D(vii).
   Exemplary Single Beam Fabrication Processes

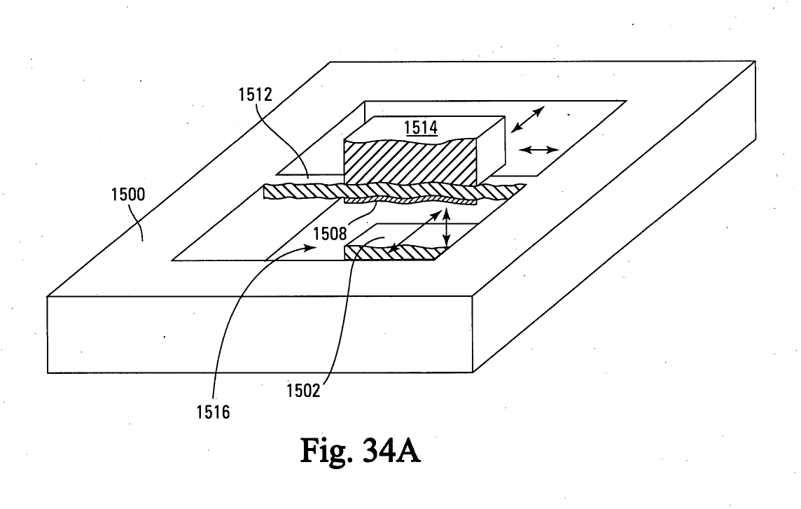

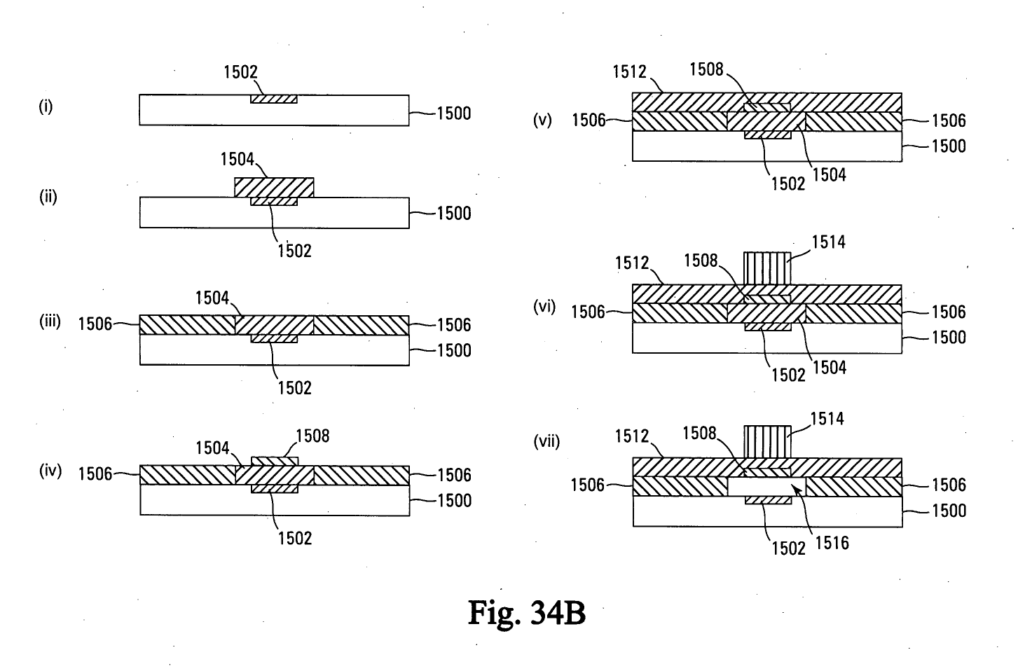

FIGS. 34A-B are combined perspective view and cross-sectional and top view block diagram illustrating exemplary processes useful in preparing a magnetic MEMS devices having a single beam member according to certain embodiments of the present invention.

FIG. 34A represents a cross-sectional perspective view of an exemplary single beam, single axis magnetic MEMS device embodiment including a substrate or base 1500, a beam member 1512 proximate to the substrate or base, extending from and adjoining the substrate at both ends of the beam member, a first magnetic field emitter element 1508 proximate to the substrate or base and attached to the beam member 1512, a first magnetic field detector element 1502 proximate to the substrate or base and positioned proximate to the magnetic field emitter element 1508 such that deflection of the beam member 1512 by a non-magnetic force results in a variation in output of the first magnetic field detector element 1502. This embodiment also illustrates an optional mass 1514 positioned on a surface of the cantilever member 1512.

FIG. 34B represents a cross-sectional view block diagram of an exemplary processing sequence useful in fabricating a magnetic MEMS device having a single beam structure as in FIG. 34A according to one embodiment of the present invention, the processing sequence including the steps of:
(i) providing a substrate or base 1500, having a first magnetic field detector element 1502;
(ii) depositing (e.g. by electroplating) a release material layer 1504 over the first magnetic field detector element 1502 on the substrate or base 1500 as shown in FIG. 34B(ii);
(iii) depositing (e.g. by electroplating or sputter deposition) a first structural material layer 1506, adjacent to the release material layer, 1504 over the first magnetic field detector element 1502, thereby covering the exposed portions of the substrate or base 1500, and planarizing (e.g. by chemical mechanical polishing) the deposited layers as shown in FIG. 34B(iii).
(iv) depositing (e.g. by electroplating or sputter deposition) a functional material (e.g. a PM material) to form a first magnetic field emitter element 1508 on the surface of the release material layer 1504;
(v) depositing (e.g. by electroplating or sputter deposition) a beam member 1512, over the entire exposed surface of the first structural material layer 1506, the release material layer 1504, and the first magnetic field emitter element 1508, as shown in FIG. 34B(v);
(vi) depositing (e.g. by electroplating or sputter deposition) an optional mass 1514, on a surface of the beam member 1512 above the first magnetic field emitter element 1508 as shown in FIG. 34B(vii);
(vii) removing (e.g. by selective wet chemical etching) the the entire release material layer 1504 to create a cavity 1516, thereby freeing the beam member 1512, bearing the first magnetic field emitter element 1508 and the optional mass 1514, and exposing the first magnetic field detector element 1502.

One skilled in the art will appreciate that multiple beams can be utilized without departing from the present invention. For example, the above embodiment could utilize two parallel beams positioned over the cavity 1516.

Exemplary Dual Crossed Beam Fabrication Processes

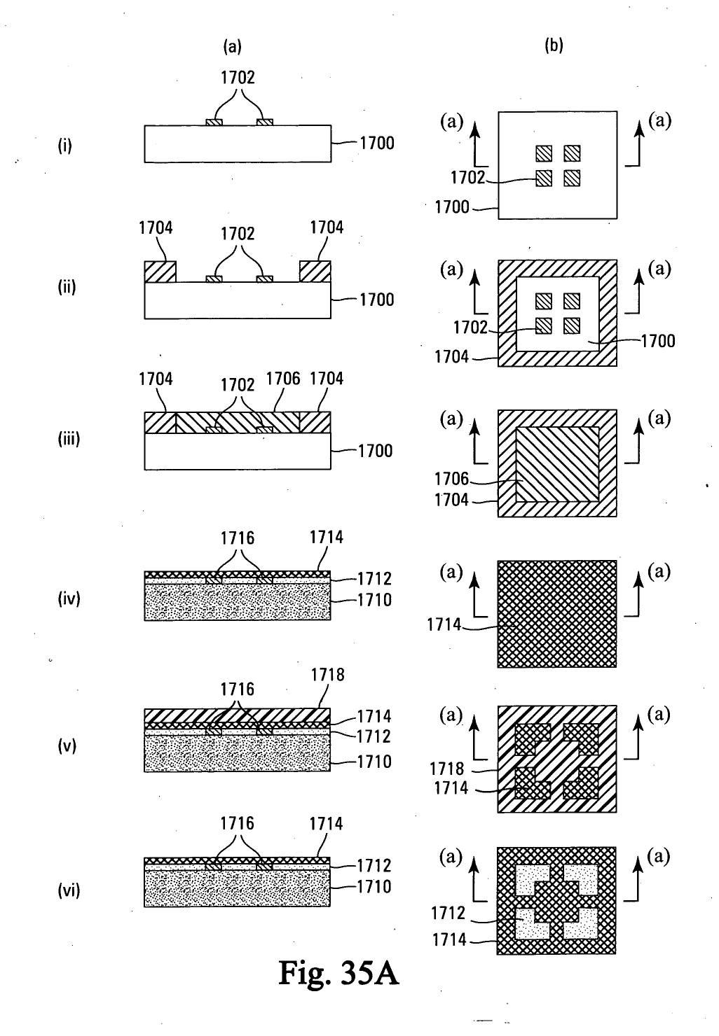

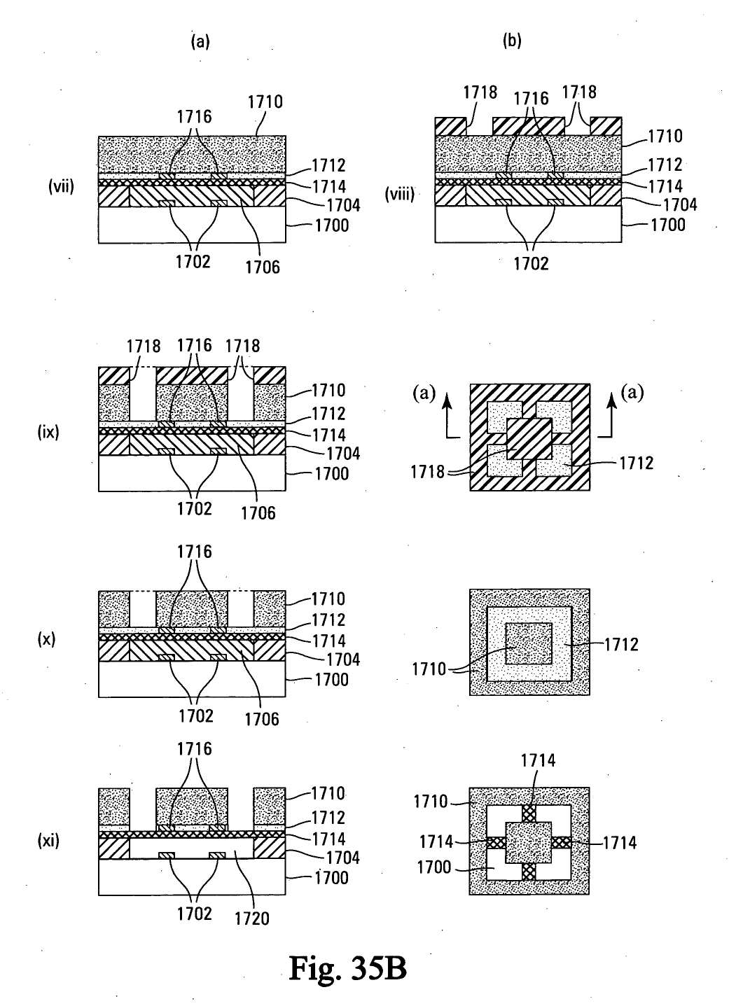

FIG. 35A-B are cross-sectional and top view block diagrams illustrating an exemplary process useful in preparing a magnetic MEMS device from two substrate or bases, the device having a plurality of magnetic field elements capable of multi-axis detection and a mass suspended above two crossed beam members according to certain embodiments of the present invention, the processing sequence including the steps of:
(i) providing a first substrate or base 1700 having one or more magnetic field detector elements 1702;
(ii) depositing (e.g. by electroplating or sputter deposition) a first structural layer material on the substrate or base 1700 to form a frame 1704 not covering the one or more magnetic field detector elements 1702;
(iii) depositing (e.g. by electroplating) a first release layer material 1706 on the exposed substrate or base surface covering the one or more magnetic field detector elements 1702 and planarizing (e.g. by chemical mechanical polishing) the deposited layers as shown in FIG. 35A(iii)(a);
(iv) providing a second substrate or base 1710 having one or more magnetic field emitter elements 1716 over which is deposited a second structural material layer 1712 and a third structural material layer 1714 as shown in FIG. 35A(iv)(a);
(v) depositing (e.g. by electroplating or sputter deposition) a first sacrificial protective layer to the surface of the third structural material layer 1714 to create a first mask 1718 as shown in FIG. 35A(v)(b);
(vi) removing (e.g. by selective wet chemical etching) that portion of the third structural material layer 1714 not protected by the first mask 1718 to form a generally rectangular frame from which are suspended two crossing beam members oriented substantially orthogonal to each other 1714, then removing the first mask 1718;
(vii) bonding (e.g. by solder bump bonding) the first substrate or base 1700 together with the second substrate or base 1710 so that the remaining third structural material layer 1714 contacts the frame 1704 of the first structural material layer and the first release layer material 1706 in face-to-face contact as shown in FIG. 35A(vi);
(viii) depositing (e.g. by electroplating or sputter deposition) a second sacrificial protective layer to the exposed surface of the second substrate or base 1710 to create a second mask 1718 as shown in FIG. 35B(viii);
(ix) selectively removing (e.g. by selective wet chemical etching) that portion of the second substrate or base 1710, the second structural material layer 1712 and the third structural material layer 1714 not protected by the second 1718 as shown in FIG. 35B(ix);
(x) removing (e.g. by selective wet chemical etching) the second sacrificial protective layer defining the second mask 1718;
(xi) removing (e.g. by selective wet chemical etching) exposed portions of the structural material 1712 (positioned between substrate or base 1710) and the first release layer material 1706 to define a crossed-beam structure 1714 and cavity 1720 as shown in FIG. 35B(ix).
   Exemplary Three Member Fabrication Process

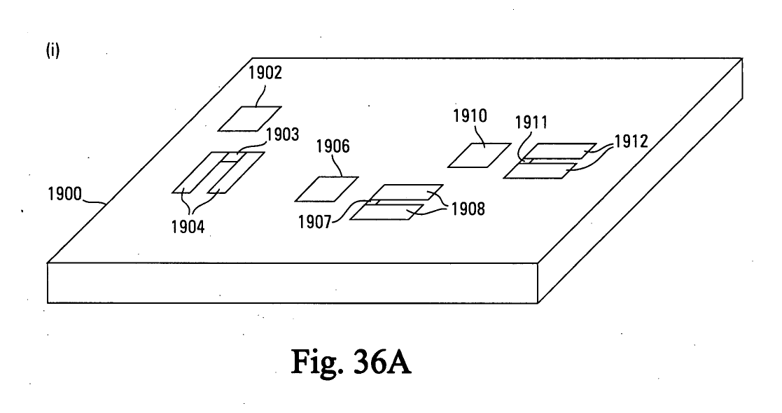

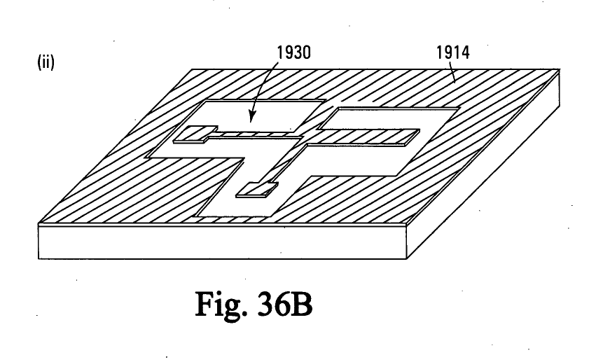

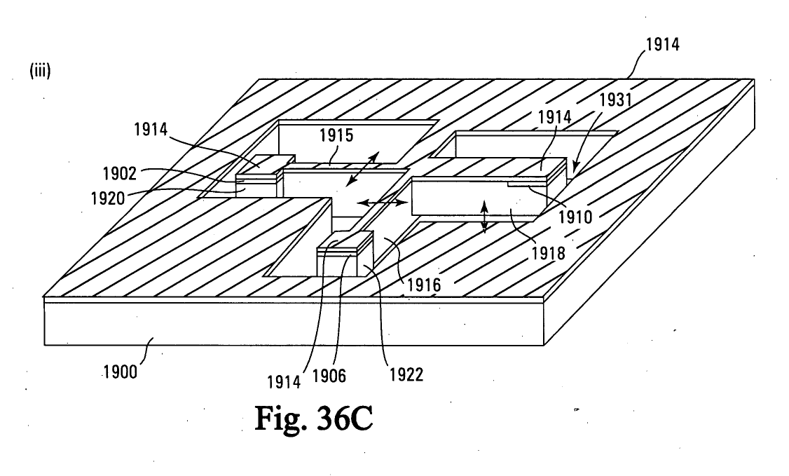

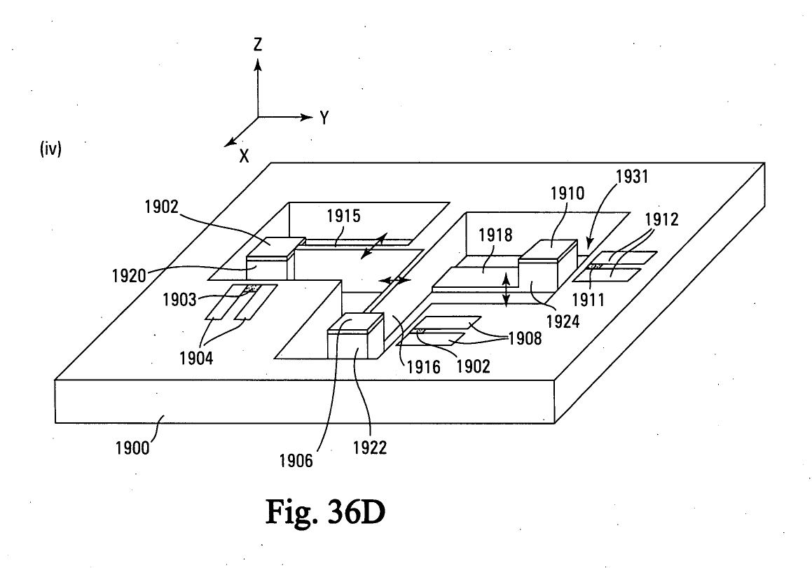

FIG. 36A-D are a perspective view block diagram illustrating an exemplary sequence of steps useful in preparing a magnetic MEMS device having three cantilever members and three magnetic field emitter-magnetic detector pairs positioned for three-axis detection, the processing sequence including the steps of:
(i) providing a substrate or base 1900 having deposited magnetic field emitter elements 1902, 1906 and 1910; and magnetic field detector elements 1903, 1907 and 1911 which are in contact with conductive leads 1904, 1908 and 1912, respectively, as shown in FIG. 36A(i);
(ii) depositing a functional layer 1914 (e.g. photoresist) and patterning (e.g. by radiant exposure and developing the exposed portions of the resist) the functional layer 1914 to define a cavity pattern 1930 as shown in FIG. 36B(ii);
(iii) removing (e.g. by etching completely or partway through the substrate or base 1900) the exposed portion of the functional material layer 1914 and the substrate or base 1900 corresponding to the cavity pattern 1930, thereby defining cantilever structures 1915, 1916 and 1918 as shown in FIG. 36C(iii);
(vi) removing (e.g. by selective wet chemical etching the residual functional material layer 1914 to produce a magnetic MEMS device having three cantilever structures 1915, 1916 and 1918 each having one of three mass structures 1920, 1922 and 1924 having magnetic field emitter elements 1902, 1906 and 1910, respectively, and positioned within the magnetic field range of magnetic field detector elements 1903, 1907 and 1911, respectively, as shown in FIG. 36D(vi).
   Exemplary Magnetic Field Detector Element Fabrication Process

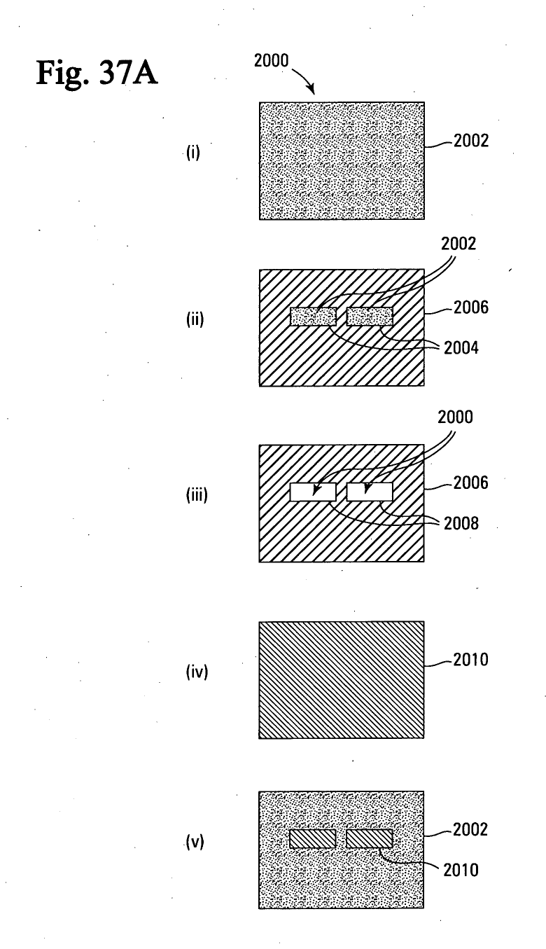

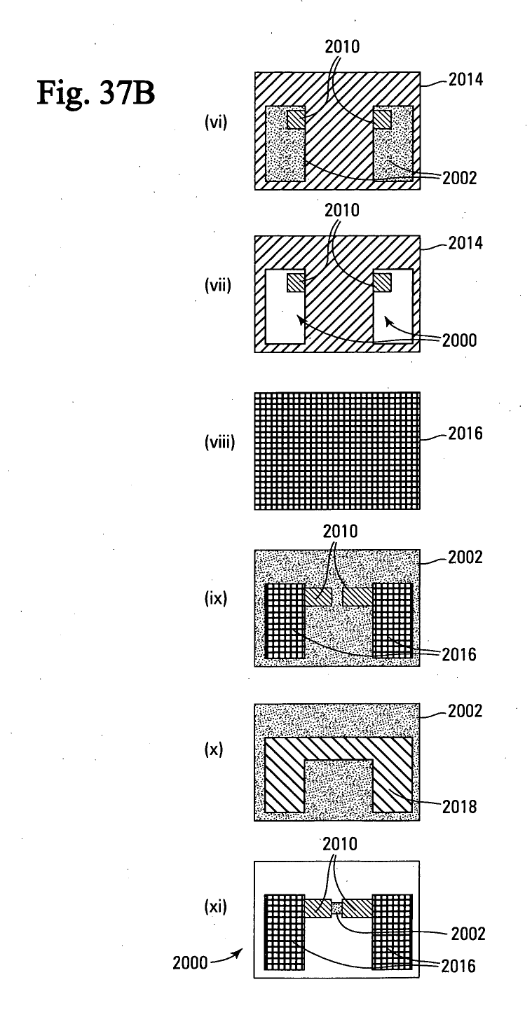

FIG. 37A-B are top view block diagrams illustrating an exemplary sequence of steps for fabricating a magnetic field detector element on a substrate or base according to an embodiment of the present invention, the processing sequence including the steps of:
(i) providing a substrate or base 2000 having a multi-layer sensor stack 2002;
(ii) depositing (e.g. by spin coating) a first functional material layer (e.g. a lift-off mask or photoresist) 2006 defining cavity patterns 2004;
(iii) removing (e.g. by ion mill etching) the multi-layer stack 2002 down to the substrate or base 2000 in the cavity pattern 2004 not protected by the first functional material layer 2006 to create cavity 2008;
(iv) depositing (e.g. by sputter deposition) a second functional material layer (e.g. a permanent magnet material) 2010 over the first-functional material layer 2006 and in cavity 2008 as shown in FIG. 37A(iv);
(v) removing (e.g. by selective wet chemical etching) the first functional material layer (e.g. a lift-off mask) 2006 as shown in FIG. 37A(v);
(vi) depositing (e.g. by spin coat) a third functional material layer (e.g. a lift-off mask) 2014 leaving exposed portion 2012 showing a portion of both muli-layer sensor stack 2002 and functional layer 2010 as shown in FIG. 37B(vi);
(vii) removing (e.g. by ion etching) the exposed portion 2012 down to substrate or base 2000 as shown in FIG. 37B(vii);
(viii) deposit (e.g. by sputter deposition) a forth functional material layer (e.g. Au or Cu) 2016 over the entire surface;
(ix) remove (e.g. lift off process) the third functional material layer 2014, which thereby also removes the portion of the forth functional material layer 2016 which is in contact with the third functional material layer 2014 as shown in FIG. 37B(ix);
(x) depositing (e.g. by spin coating) a fifth functional material layer (e.g. a photoresist material) over the entire surface, then expose and develop the fifth functional material layer to define mask 2018 as shown in FIG. 37B(x);
(xi) removing the fifth functional material layer 2018 to create a magnetic field detector element having multi-layer sensor stack 2002 with permanent magnets 2010 adjacent each side of the multi-layer sensor stack 2002, further having conductive leads 2016 in contact with the permanent magnets 2010 as shown in FIG. 37B(xi).
   Exemplary Magnetic Field Emitter Element Fabrication Process

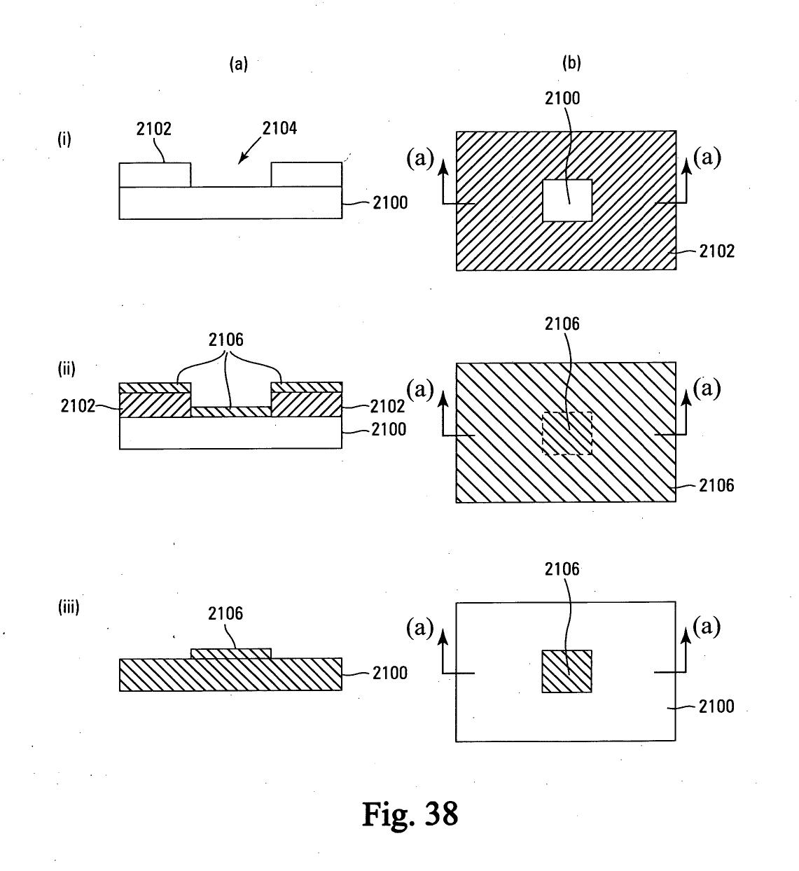

FIG. 38 is a (a) cross-sectional and (b) top view block diagram illustrating an exemplary sequence of steps for fabricating a magnetic field emitter element on a substrate or base according to an embodiment of the present invention, the processing sequence including the steps of:
(i) providing a substrate or base 2100 and depositing (e.g. by electroplating) a first functional material layer (e.g. a resist) 2102 to the surface of the substrate or base 2100 to define a cavity 2104;
(ii) depositing (e.g. by sputter deposition) a second functional material layer (e.g. a permanent magnet material) on the entire surface;
(iii) removing (e.g. by chemical etching) the first functional material layer 2102 (and portions of the second functional layer material 2106 which are on top of first functional layer material 2102) to yield a magnetic field emitter element 2106 on a surface of the substrate or base 2100.
   Exemplary Process to Fabricate Magnetic MEMS Device with a Membrane Member

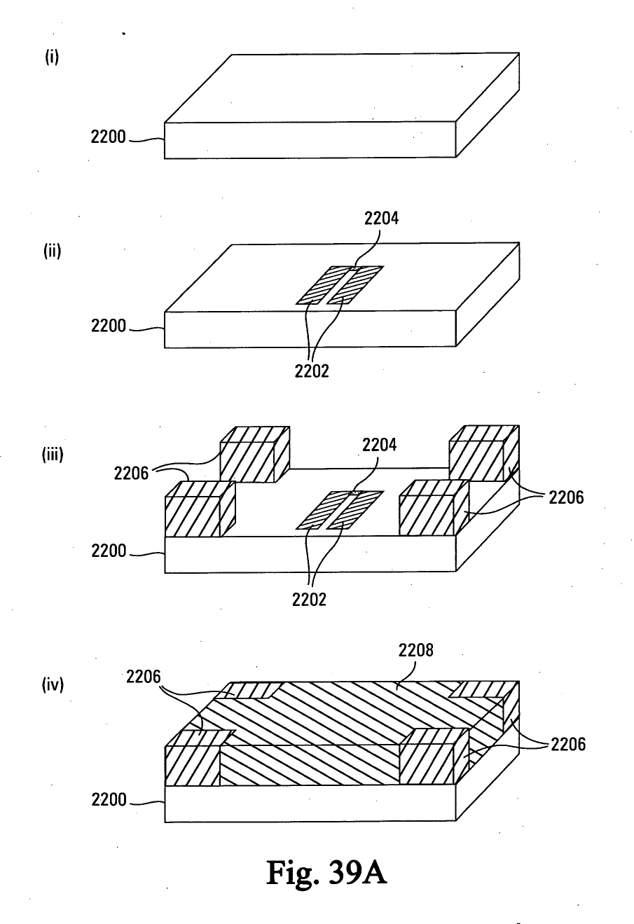

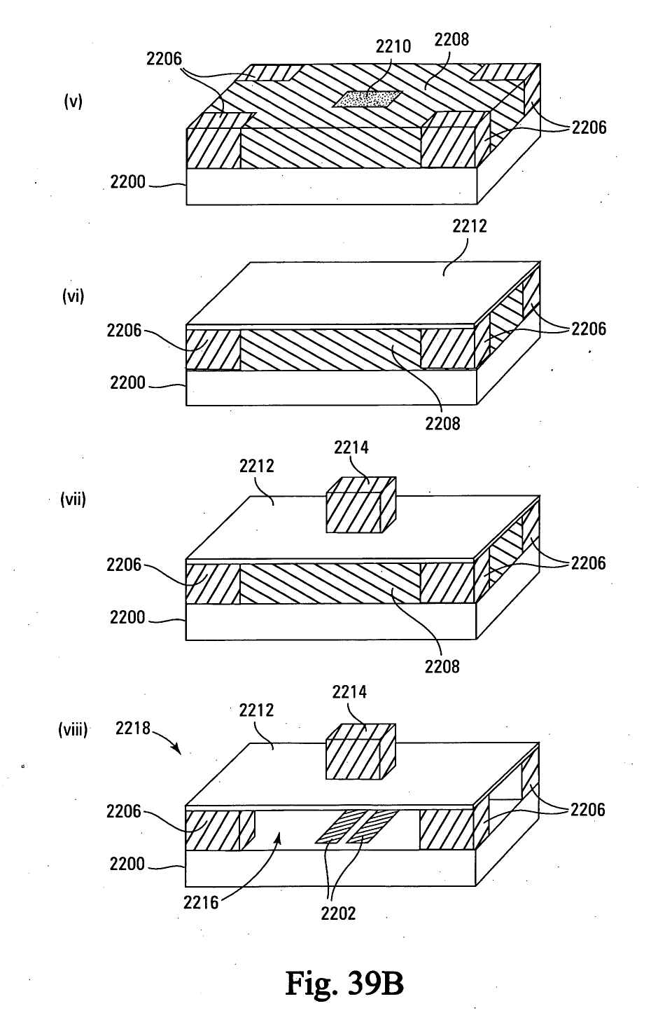

FIGS. 39A and 39B, both perspective views, represent one exemplary processing sequence useful in fabricating a magnetic MEMS device having a membrane member according to one embodiment of the present invention, the processing sequence including the steps of:
(i) providing a substrate or base 2200;
(ii) depositing a magnetic field detector 2204 and electrical connections 2202 on substrate or base 2204;
(iii) depositing (e.g. by electroplating or sputter deposition) a structural material layer 2206 portions of the substrate or base 2200;
(iv) depositing (e.g. by electroplating or sputter deposition) a release material 2208 on the exposed portion of the substrate or base 2200, and planarizing in plane with structural material 2206;
(v) depositing (e.g. by electroplating or sputtering) a functional material layer to form a magnetic field emitter element 2210 on the surface of the release material layer 2208 as shown in FIG. 39B;
(vi) depositing (e.g. by electroplating or sputter deposition) a structural material layer to form membrane member 2212 extending at least over the structural material 2206;
(vii) depositing an optional mass 2214 on the membrane member 2212 generally above the magnetic field emitter element 2210;
(viii) removing (i.e. by etching) the release material layer 2208 through exposed portions of membrane member 2212 to form cavity 2216.
   Exemplary Magnetic MEMS Devices
   Displacement Sensors

In exemplary embodiments, magnetic MEMS devices fabricated according to the present invention are useful as displacement sensors. Preferably, displacement sensors are selected to match a desired displacement range, with sensors using cantilever structures as members preferably being used for measuring large displacements under load force load, and sensors using beam or membrane structures being used to measure small deflections under high force load. The elasticity and/or force constant of the member can, in some preferred embodiments, be altered according to the desired force or, displacement sensitivity by varying the dimensions of the member (i.e. thickness, width, and length) or by varying the nature of the structural material which comprises the member.

For example, this relationship can be expressed by the following equation:

$$d = \frac{12}{Ew} {( \frac{l}{t} )}^{3} F$$

where d is displacement of the end of the member, E is Young's modulus of the member material, w is width of the member, t is thickness of the member, l is length of the member, and F is the external force acting on the member. The mutual separation between the magnetic field emitter and detector elements is measured by the detector and an output is generated. This output is based on the displacement of the member as an external force acts upon the member. By knowing the width, length, thickness, Young's modulus, and displacement of the member, a force acting upon the member can be determined and hence an acceleration of the entire system can be determined. The calculation of acceleration of the entire system will vary depending on other factors such as strength of the magnetic field emitter, sensitivity of the magnetic field detector, and mutual separation of the emitter and detector. The relationship described above is applicable to all magnetic MEMS devices.
Force or Shock Sensors

In exemplary embodiments, structures fabricated according to the present invention are useful as force or shock sensors. Preferably, force or shock sensors are selected to match a desired force or shock loading, with sensors using cantilever structures as members preferably being used for measuring low force loads or shocks, and sensors using beam or membrane structures being used to measure high force loads or shocks.

Magnetic Pressure Devices

In some preferred embodiments, a magnetic pressure device is fabricated using exemplary structures and fabrication methods according to the present invention. Magnetic pressure devices generally measure an integrated force per unit of surface area upon which that force is exerted.

Preferred magnetic pressure devices generally make use of members that are single beam, dual beam, or membrane structures. Most preferably, the magnetic pressure devices make use of a membrane structure.

Accelerometers

In exemplary embodiments, structures fabricated according to the present invention are useful as accelerometers. Linear accelerometers, rotary accelerometers, and paired linear accelerometers (simulating rotary accelerometers) can be providing using various embodiments according to the present invention. In addition, accelerometers providing single axis, two axis, three axis and multi-axis acceleration detection are provided by certain preferred embodiments of the present invention.

Higher Sensitivity Accelerometers

The elasticity and/or force constant of the member can, in some embodiments, be altered according to the desired force or displacement sensitivity by varying the thickness of the member or by varying the nature of the structural material which comprises the member.

In certain preferred embodiments, an improved sensitivity accelerometer is provided by using two or more magnetic field emitter-magnetic field detector pairs to determine displacement of the member. In certain more preferred embodiments, accelerometers capable of multi-axis acceleration detection are provided by using a plurality of magnetic field emitter-magnetic field detector pairs to determine displacement of the member.

Accelerometers for Low-g Environments

In some embodiments, magnetic MEMS devices using cantilever structures as members are particularly well suited for use in low acceleration (i.e. a fraction of a gravitational force) environments where high sensitivity detection of a displacement or force is desired. The acceleration of the member can, in some embodiments, be altered according to the desired g-force range or desired force or displacement sensitivity by varying the mass of the member (e.g. by including an optional mass), thickness of the member or by varying the nature of the structural material that comprises the member (e.g. varying the modulus by changing the material from which the member is fabricated).

Accelerometers for High-g Environments

Some applications require the measurement of a force or acceleration in extreme dynamic environments. For example, if a gun-launched projectile requires on-board acceleration sensing, the accelerometer providing the sensing must not only have high sensitivity, but also must be capable of operating in a high-g range with high-g shock survivability characterized by shock loads typically in the range of 16,000 to 20,000 g's or more. However, such high-g environments can cause sensor failure.

Accelerometers based on members that are cantilever structures can be made more durable by various means, including but not limited to increasing device spring constant. However, increasing device force constant typically reduces device signal strength and sensitivity.

Alternatively, single beam, dual parallel beam, or cross-beam structures can preferably be used to provide members of progressively greater ability to measure high g accelerations and may withstand high g forces without damage to the present invention.

For high-g applications, a fast reacting accelerometer device is often desired. Fast device response generally requires a member exhibiting a high resonant frequency. However, for the member to exhibit a high resonant frequency, it would generally need to have a very large suspension and/or high spring force constant. This would typically limit the sensitivity, and thus the dynamic range, of the accelerometer.

In exemplary multiple beam/multiple magnetic magnetic field element embodiments, the present invention can be used to providing accelerometers that are higher performance, including but not limited to larger dynamic range. These multiple beam/multiple magnetic field element embodiments can also be used to provide accelerometers with improved manufacturability and survivability in high g-force environments.

Gyroscopes

In some preferred embodiments, a gyroscope is fabricated using exemplary structures and fabrication methods according to the present invention. Gyroscopes fabricated using magnetic MEMS technology conventionally make use of the Coriolis effect to sense motion relative to a fixed axis, meaning the member, preferably bearing a magnetic field emitter element, is made to oscillate at a fixed amplitude in one plane or along an axis of the gyroscope. The turning rate experienced by the gyroscope along that axis alters the amplitude of the member, which produces a variation in magnetic field strength or flux at a magnetic field detector element.

Atomic Force Microscope

In some preferred embodiments, it is contemplated that the present invention is applicable to atomic force microscopes. For example, a dual cantilever member structure could be used. A detector is positioned on one cantilever member, while an emitter is positioned on the other cantilever member. The position of the emitter and detector are interchangeable. One of the cantilever members would have a tip for scanning a surface of a sample. The cantilever member will move as the tip follows the topography of the sample, so that the deflection of the cantilever member by the non-magnetic force produces a detectable variation in magnetic field strength at the detector element.

Acoustic Wave Measurement Device

In some preferred embodiments, it is contemplated that the present invention is applicable to acoustic wave measurement devices. For example, beam or membrane structure could be used. A detector is positioned on the beam or membrane, while an emitter is positioned on the substrate or base. The position of the emitter and detector are interchangeable. The acoustic wave will displace the membrane or beam. The deflection of the cantilever member by the non-magnetic force produces a detectable variation in magnetic field strength at the detector element.

pH Measurement Device

In some preferred embodiments, it is contemplated that the present invention is applicable to pH value measurement devices. For example, a dual cantilever member structure could be used. A detector is positioned on one cantilever member, while an emitter is positioned on the other cantilever member. The position of the emitter and detector are interchangeable. A pH sensitive material is positioned proximate one of the members, and the test sample is positioned adjacent the sensitive material. The sensitive material will expand or contracts due to depending on the chemistry of the test sample, and in turn the member proximate the sensitive material will move. The deflection of the cantilever member by the non-magnetic force produces a detectable variation in magnetic field strength at the detector element.

Mass Flow Measurement device

In some preferred embodiments, it is contemplated that the present invention is applicable to mass flow measurement devices. For example, a dual cantilever member structure could be used. A detector is positioned on one cantilever member, while an emitter is positioned on the other cantilever member. The position of the emitter and detector are interchangeable. The dual cantilever would extend from a substrate or base and be positioned proximate an aperture formed in the substrate or base to allow for mass flow. The mass flow through the aperture will displace the cantilever member. The deflection of the cantilever member by the non-magnetic force produces a detectable variation in magnetic field strength at the detector element, thus measuring the mass flow. The two members can be in side-by-side or up-and-down position with respect to the flow. The double cantilever structure can be positioned parallel or perpendicular to the flow.

It is to be understood that even though numerous characteristics and advantages of various embodiments of the present invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed.

We claim:

1. A micro-electro-mechanical system comprising:
a base;
a member adjoined to the base;
a first magnetic field emitter having an intrinsic magnetic moment;
a magnetic sensor having an altered output associated with movement of the member and the intrinsic magnetic moment of the magnetic field emitter.

2. The micro-electro-mechanical system of claim 1, wherein the magnetic sensor is adjoining the member.

3. The micro-electro-mechanical system of claim 2, wherein the first magnetic field emitter is positioned on the base.

4. The micro-electro-mechanical system of claim 1, wherein the first magnetic field emitter positioned on the member.

5. The micro-electro-mechanical system of claim 4, wherein the magnetic sensor is adjoining the base.

6. The micro-electro-mechanical system of claim 5, wherein the first magnetic field emitter element is at least one of a permanent magnet, a ferromagnetic material, a paramagnetic material, a solenoid or an electromagnet.

7. The micro-electro-mechanical system of claim 1, wherein the member is at least one of a cantilever, a single beam, two parallel beams, two crossed beams or a membrane.

8. The micro-electro-mechanical system of claim 1, wherein the magnetic sensor is at least one of a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant magneto-impedence sensor, a tunneling giant magneto-resistive sensor, or an anisotropic magneto-resistive sensor.

9. The micro-electro-mechanical system of claim 1, wherein a flux guide is positioned proximate to the magnetic sensor.

10. The micro-electro-mechanical system of claim 1, wherein the member is a cantilever and the magnetic sensor is positioned proximate to the member, and wherein a first magnetic field emitter is adjoined to the base.

11. The micro-electro-mechanical system of claim 10, further comprising a second magnetic field emitter positioned proximate to the base opposite the first magnetic field emitter.

12. The micro-electro-mechanical system of claim 11, wherein the base defines a cavity, and wherein the first magnetic field emitter is positioned proximate to the cavity.

13. The micro-electro-mechanical system of claim 12, further comprising a substrate positioned over the cavity, wherein a second magnetic field emitter is positioned proximate to the substrate.

14. The micro-electro-mechanical system of claim 1, wherein the member is a beam and the magnetic sensor is adjoining the member, and wherein the first magnetic field emitter is positioned proximate to the base.

15. The micro-electro-mechanical system of claim 14, wherein the base defines a cavity and wherein the first magnetic field emitter is positioned proximate to the cavity.

16. The micro-electro-mechanical system of claim 14, further comprising a second magnetic field emitter positioned proximate to the member opposite the first magnetic field emitter.

17. The micro-electro-mechanical system of claim 1, wherein the first member is a membrane and the first magnetic sensor is adjoining the first member, and wherein a first magnetic field emitter is positioned proximate the base.

18. An electronic device comprising:
a substrate;
a first member extending from the substrate;
a first magnetic field element adapted to do at least one of emit or detect a magnetic field, wherein the first magnetic element is positioned proximate to the first member; and
a second magnetic field element adapted to do at least one of emit or detect a magnetic field, wherein the second magnetic field element is positioned proximate to the substrate, and wherein movement of the first member in a first direction by a non-magnetic force results in a variation of magnetic field strength associated with displacement in a first direction.

19. The electronic device according to claim 18, further comprising at least one electronic circuit formed on or within said substrate, said at least one electronic circuit communicably adjoining said first magnetic field emitter element and said first magnetic field detector element.

20. The electronic device according to claim 19, wherein said at least one electronic circuit includes at least one electronic circuit element selected from the group consisting of a via, an electrode, a power source, a pre-amplifier, a modulator, a demodulator, a filter, an analog to digital computer, a digital to analog converter, or a digital signal processor.

21. The electronic device of claim 18, wherein the substrate includes a cavity.

22. The electronic device of claim 21, wherein the first member includes a free end distal from a connected end, the connected end adjoining the substrate and the free end adjoining the first magnetic field element, and wherein the first member at least partially covers the cavity;
a second member approximately substantially orthogonal to the first member, wherein the second member includes a free end distal from a connected end, the connected end adjoining the substrate and the free end adjoining a third magnetic field element, and wherein the second member at least partially covers the cavity;
a third member approximately substantially orthogonal to the second member, wherein the second member has a free end distal from a connected end, the connected end adjoining the substrate and the free end adjoining a fourth magnetic field element, further wherein the third member at least partially covers the cavity;
a fifth magnetic field element extending from the substrate and positioned to detect or emit a magnetic field associated with the third magnetic field element wherein movement of the second member by a non-magnetic force results in a variation of magnetic field strength associated with displacement in a second direction; and
a sixth magnetic field element adjoining the substrate and positioned to detect or emit a magnetic field associated with the fourth magnetic field element wherein movement of the third member by a non-magnetic force results in a variation of magnetic field strength associated with displacement in a third direction.

23. The electronic device according to claim 22, wherein each of the first and second, third and fifth, and the fourth and sixth magnetic field elements form a magnetic field emitter-magnetic field detector pair.

24. The electronic device according to claim 22, wherein each of the first, second and third members is a three-dimensional, substantially rectangular cantilever having one dimension thinner than the other two, and each cantilever is oriented such that its thinner dimension is oriented perpendicular to but not co-planar with the thinner dimensions of each of the other two cantilevers.

25. The electronic device of claim 21, wherein the first member is a cantilever having a free end distal from a connected end; the free end having a mass containing the first magnetic field element, and positioned to at least partially cover the cavity; and the connected end adjoining the substrate.

26. The electronic device of claim 25, wherein the second magnetic field element comprises a plurality of magnetic field detector elements arranged in a two-dimensional planar array on the substrate within the cavity.

27. The electronic device of claim 21, wherein the first member is a beam extending over the cavity, the beam comprising a mass containing the first magnetic field element, further wherein the second magnetic field element comprises a plurality of magnetic field detector elements arranged in a two-dimensional planar array on the substrate within the cavity.

28. The electronic device of claim 27, wherein the beam further comprises a third and fourth magnetic field element.

29. The electronic device of claim 28, wherein the third and fourth magnetic field elements each comprise a magneto-strictive sensor.

30. The electronic device of claim 18, wherein the first magnetic field element is selected from the group consisting of a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant-magneto-impedence sensor, a tunneling giant magneto-resistive sensor, or an anisotropic magneto-resistive sensor.

31. The electronic device of claim 18, wherein the first magnetic field element is selected from the group consisting of a permanent magnet, a ferromagnetic material, a paramagnetic material, a solenoid and an electromagnet.

32. A transducer comprising:
a substrate;
a first member extending from the substrate;
a first magnetic field emitter element adjoining the substrate, wherein the first magnetic field emitter element has an intrinsic magnetic moment; and
a first magnetic field detector element adjoining the substrate and positioned within a magnetic field of the magnetic field emitter element, wherein the detect has an altered output associated with movement of the first member by a non-magnetic force and the intrinsic magnetic moment of the emitter.

33. The transducer according to claim 32, further comprising at least one electronic circuit formed on or within said substrate, said at least one electronic circuit communicably adjoining said first magnetic field emitter element and said first magnetic field detector element.

34. The transducer according to claim 33, wherein said at least one electronic circuit includes at least one electronic circuit element selected from the group consisting of a via, an electrode, a power source, a pre-amplifier, a modulator, a demodulator, a filter, an analog to digital computer, a digital to analog converter, or a digital signal processor.

35. The transducer according to claim 32, further comprising a mass adjoining the first member.

36. The transducer according to claim 32, wherein movement of the first member to result in a variation in magnetic field strength at the first magnetic field detector element is calibrated to sense one or more of a displacement, a force, a pressure and an acceleration applied to the first member.

37. The transducer according to claim 32, wherein the first magnetic field detector element is positioned such that movement along a first and second axis of the first member alters an output of the first magnetic field detector element in proportion to the movement of the member along the first and second axis.

38. The transducer according to claim 32, wherein the substrate is made from at least one of the materials in the group consisting of polysilicon, single crystalline silicon, silicon-germanium, silicon carbide, silicon oxide, silicon dioxide, silicon nitride, silicon oxynitrite, metals, metal alloys, ceramics, or polymers.

39. The transducer according to claim 32, wherein the substrate comprises a single crystal semi-conductor device.

40. The transducer of claim 32, wherein the first member is selected from the group consisting of a cantilever, a single beam, two parallel beams, two crossed beams and a membrane.

41. The transducer according to claim 40, wherein the first member is a membrane hermetically sealed to the substrate.

42. The transducer of claim 32, wherein the first magnetic field emitter element is selected from the group consisting of a permanent magnet, a ferromagnetic material, a paramagnetic material, a solenoid and an electromagnet.

43. The transducer of claim 32, wherein the first magnetic field detector element is at least one of a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant magneto-impedence sensor, a tunneling giant magneto-resistive sensor or an anisotropic magneto-resistive sensor.

44. The transducer of claim 32, further comprising a second magnetic field detector element adjoining the substrate and positioned such that movement of the first member alters an output of at least one of the first and second magnetic field detector elements.

45. The transducer of claim 44, wherein the variation in an output of the first magnetic field detector element is greater than an output of the second magnetic field detector element.

46. The transducer of claim 44, wherein the first magnetic field detector element is positioned such that movement along a first axis of the first member alters an output of the first magnetic field detector element in proportion to the movement of the first member along the first axis, further wherein the second magnetic field detector element is positioned such that movement along a second axis of the first member alters an output of the first magnetic field detector element in proportion to the movement of the first member along the first axis.

47. The transducer of claim 44, wherein the first magnetic field detector element is positioned such that movement along a first and second axis of the first member alters an output of the first magnetic field detector element in proportion to the movement of the first member along the first and second axis, further wherein the second magnetic field detector element is positioned such that movement along a third axis of the first member alters an output of the first magnetic field detector element in proportion to the movement of the first member along the third axis.

48. The transducer of claim 32, further comprising a second member extending from the substrate, a second magnetic field emitter element adjoining the substrate, a second magnetic field detector element adjoining the substrate and positioned within a magnetic field of the second magnetic field emitter element such that movement of the second member by a non-magnetic force results in the output of the second magnetic field detector element.

49. The transducer of claim 48, further comprising a third member extending from the substrate, a third magnetic field emitter adjoining the substrate, a third magnetic field detector element adjoining the substrate and positioned within a magnetic field of the third magnetic field emitter element such that movement of the third member by a non-magnetic force results in a variation in output of the third magnetic field detector element.

50. The transducer of claim 49, wherein each of the first, second and third members is a three-dimensional rectangular cantilever having first dimension, a second dimension and a third dimension, further wherein the first dimension is larger than the second and third dimension.

51. The transducer of claim 50, wherein the substrate has a x-axis, a y-axis, and a z-axis, further wherein the first member is aligned co-planar with the x-axis, the second member is aligned co-planar with the y-axis, and the third member is aligned co-planar with the z-axis.

52. The transducer of claim 32, wherein the substrate has a cavity formed therein and the first member extends across the cavity.

53. The transducer of claim 52, further comprising a second member extending across the cavity substantially orthogonal to the first member.

54. The transducer of claim 53, wherein the first magnetic field detector element is positioned on the first member and an output of the first magnetic field a detector is altered by a non-magnetic force in a first direction.

55. The transducer of claim 54, further comprising a second magnetic field detector element positioned on the first member, wherein an output of the second magnetic field detector is altered by a non-magnetic force in a second direction.

56. The transducer of claim 55, further comprising a third magnetic field detector element positioned on the first member, wherein an output of the third magnetic field detector element is altered by a non-magnetic force in a third direction.

57. The transducer of claim 56, further comprising a fourth magnetic field detector element positioned on the second member, wherein an output of the fourth magnetic field detector element is altered by a non-magnetic force in the first direction.

58. The transducer of claim 57, further comprising a fifth magnetic field detector element positioned on the second member, wherein an output of the fifth magnetic field detector element is altered by a non-magnetic force in the second direction.

59. The transducer of claim 58, further comprising a sixth magnetic field detector element positioned on the second member, wherein an output of the sixth magnetic field detector element is altered by a non-magnetic force in the third direction.

60. A sensor comprising:
a base;
a member extending from the base;
a magnetic field element having an intrinsic magnetic moment; and
a transducer means for sensing variation in a magnetic field, wherein the variation of the magnetic field is related to movement of the member and the intrinsic magnetic moment of the magnetic field element.

61. The sensor of claim 60, wherein the transducer means is at least one of a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant magneto-impedence sensor, a tunneling giant magneto-resistive sensor or an anisotropic magneto-resistive sensor.

62. The sensor of claim 60, wherein the magnetic field element is a magnetic field emitter positioned proximate to the base member.

63. The sensor of claim 62, wherein the magnetic field emitter is at least one of a permanent magnet, a ferromagnetic material, a paramagnetic material, a solenoid or an electromagnet.

64. The sensor of claim 62, wherein the transducer means is positioned proximate to the base.

65. The sensor of claim 60, wherein the magnetic field element is positioned proximate to the member.

66. The sensor of claim 65, wherein the transducer means is positioned proximate to the base.

67. The sensor of claim 60, wherein the member is at least one of a cantilever, a single beam, two parallel beams, two crossed beams or a membrane.

68. The sensor of claim 60, wherein the base defines a cavity.

69. The sensor of claim 68, wherein the member is a cantilever positioned to partially cover the cavity, and wherein the transducer means is positioned proximate to the member.

70. The sensor of claim 69, wherein the magnetic field element is a magnetic field emitter.

71. The sensor of claim 70, wherein the magnetic field emitter is positioned proximate to the cavity.

72. An accelerometer comprising:
a detector having an output, wherein the output fluctuates when subjected to magnetic flux; and
a first emitter having an intrinsic magnetic moment which transmits magnetic flux, wherein movement of the accelerometer and the intrinsic magnetic moment of the first emitter results in variation of the output of the detector.

73. The accelerometer of claim 72, wherein the detector is at least one of a magneto-electric sensor, a magneto-resistive sensor, a magneto-impedence sensor, a magneto-strictive sensor, a flux guided magneto-resistive sensor, a giant magneto-resistive sensor, a giant magneto-electric sensor, a giant magneto-impedence sensor, a tunneling giant magneto-resistive sensor or an anisotropic magneto-resistive sensor.

74. The accelerometer of claim 72, wherein the first emitter is at least one of a permanent magnet, a ferromagnetic material, a paramagnetic material, a solenoid or an electromagnet.

75. The accelerometer of claim 72, further comprising a substrate and a member extending from the substrate.

76. The accelerometer of claim 75, wherein the first emitter is positioned proximate to the first member.

77. The accelerometer of claim 76, wherein the detector is positioned proximate to the substrate.

78. The accelerometer of claim 77, wherein the accelerometer further comprises a second emitter having an intrinsic magnetic moment that transmits magnetic flux, further wherein the second emitter is positioned proximate to the base.

79. The accelerometer of claim 78, wherein the first and second emitters are positioned on opposite sides of the detector.

80. The accelerometer of claim 75, wherein the substrate defines a cavity, and wherein the first emitter is positioned proximate to the cavity..

81. The accelerometer of claim 75, wherein the first emitter is comprised of a plurality of permanent magnets positioned proximate to the substrate.

82. The accelerometer of claim 81, wherein the detector is positioned proximate to the first member.
